(19) United States
(12) Patent Application Publication
(10) Pub. No.: US 2026/0338466 A1
(43) Pub. Date: Oct. 29, 2026

(54) FLUID SUPPLY SYSTEM, SUBSTRATE PROCESSING APPARATUS AND SUBSTRATE PROCESSING METHOD

(71) Applicant: Tokyo Electron Limited, Tokyo (JP)

(72) Inventors: Takahiro HAYASHIDA, Koshi City, Kumamoto (JP); Shota UMEZAKI, Koshi City, Kumamoto (JP); Mikio NAKASHIMA, Koshi City, Kumamoto (JP)

(73) Assignee: Tokyo Electron Limited, Tokyo (JP)

(21) Appl. No.: 19/122,265

(22) PCT Filed: Jul. 14, 2023
(86) PCT No.: PCT/JP2023/026064

§ 371 Date: Apr. 18, 2025

(30) Foreign Application Priority Data
Oct. 20, 2022 (JP) 2022-168324

(51) Int. Cl. F26B 5/00; H10P 72/00

(52) U.S. Cl. CPC F26B 5/005; H10P 72/0402

(57) ABSTRACT

A fluid supply system for supplying a fluid into a processing container in which a substrate is processed includes a processing fluid supply for supplying a processing fluid; a fluid supply line, connected to the processing fluid supply and the processing container, for allowing a temperature-adjusted processing fluid to flow inside the processing container; a first heating mechanism, provided in the fluid supply line, for heating the processing fluid to a first temperature; and a second heating mechanism, provided in the fluid supply line, for heating the processing fluid to a second temperature lower than the first temperature. The processing fluid supply is equipped with a flow rate adjustment mechanism. The fluid supply line includes a first branch line for allowing the processing fluid to pass through the first heating mechanism; and a second branch line for allowing the processing fluid to pass through the second heating mechanism.

### TECHNICAL FIELD

The various aspects and embodiments described herein pertain generally to a fluid supply system, a substrate processing apparatus, and a substrate processing method.

### BACKGROUND

There is known a technology of drying a substrate using a supercritical fluid. Patent Document 1 discloses a configuration to change a temperature of a supercritical fluid supplied to a substrate.

### PRIOR ART DOCUMENT

Patent Document 1: Japanese Patent Laid-open Publication No. 2021-086857

### DISCLOSURE OF THE INVENTION

### Problems to be Solved by the Invention

The present disclosure provides a technology capable of supplying a processing fluid with controlled flow rate and temperature.

### Means for Solving the Problems

In one exemplary embodiment, a fluid supply system configured to supply a fluid into a processing container in which a substrate is processed includes: a processing fluid supply configured to supply a processing fluid; a fluid supply line connected to the processing fluid supply and the processing container, and configured to allow a temperature-adjusted processing fluid to flow inside the processing container; a first heating mechanism provided in the fluid supply line and configured to heat the processing fluid to a first temperature; and a second heating mechanism provided in the fluid supply line and configured to heat the processing fluid to a second temperature lower than the first temperature. The processing fluid supply is equipped with a flow rate adjustment mechanism configured to adjust a flow rate of the processing fluid. The fluid supply line is equipped with: a first branch line configured to allow the processing fluid to pass through the first heating mechanism and then flow inside the processing container; and a second branch line configured to allow the processing fluid to pass through the second heating mechanism and then flow inside the processing container.

### Effects of the Invention

According to the present disclosure, it is possible to supply the processing fluid with the controlled flow rate and temperature.

### BRIEF DESCRIPTION OF THE DRAWINGS

FIG. 1 is a view illustrating a substrate processing apparatus according to a first exemplary embodiment.

FIG. 2 is a timing chart illustrating a substrate processing method according to the first exemplary embodiment.

FIG. 3 is a first view illustrating the substrate processing method according to the first exemplary embodiment.

FIG. 4 is a second view illustrating the substrate processing method according to the first exemplary embodiment.

FIG. 5 is a third view illustrating the substrate processing method according to the first exemplary embodiment.

FIG. 6 is a fourth view illustrating the substrate processing method according to the first exemplary embodiment.

FIG. 7 is a fifth view illustrating the substrate processing method according to the first exemplary embodiment.

FIG. 8 is a sixth view illustrating the substrate processing method according to the first exemplary embodiment.

FIG. 9 is a seventh view illustrating the substrate processing method according to the first exemplary embodiment.

FIG. 10 is a view illustrating a substrate processing apparatus according to a second exemplary embodiment.

FIG. 11 is a timing chart illustrating a substrate processing method according to the second exemplary embodiment.

FIG. 12 is a first view illustrating the substrate processing method according to the second exemplary embodiment.

FIG. 13 is a second view illustrating the substrate processing method according to the second exemplary embodiment.

FIG. 14 is a third view illustrating the substrate processing method according to the second exemplary embodiment.

FIG. 15 is a fourth view illustrating the substrate processing method according to the second exemplary embodiment.

FIG. 16 is a fifth view illustrating the substrate processing method according to the second exemplary embodiment.

FIG. 17 is a sixth view illustrating the substrate processing method according to the second exemplary embodiment.

FIG. 18 is a seventh view illustrating the substrate processing method according to the second exemplary embodiment.

FIG. 19 is a view illustrating a substrate processing apparatus according to a first modification example of the second exemplary embodiment.

FIG. 20 is a view illustrating a substrate processing apparatus according to a second modification example of the second exemplary embodiment.

FIG. 21 is a view illustrating a substrate processing apparatus according to a third exemplary embodiment.

FIG. 22 is a view illustrating a substrate processing apparatus according to a fourth exemplary embodiment.

FIG. 23 is a view illustrating a substrate processing apparatus according to a fifth exemplary embodiment.

FIG. 24 is a view illustrating a substrate processing apparatus according to a sixth exemplary embodiment.

### DETAILED DESCRIPTION

Hereinafter, non-limiting exemplary embodiments of the present disclosure will be described with reference to the accompanying drawings. In the drawings, the same or corresponding members or components are denoted by the same or corresponding reference symbols, and overlapping descriptions thereof will be omitted.

### First exemplary embodiment

### Substrate Processing Apparatus

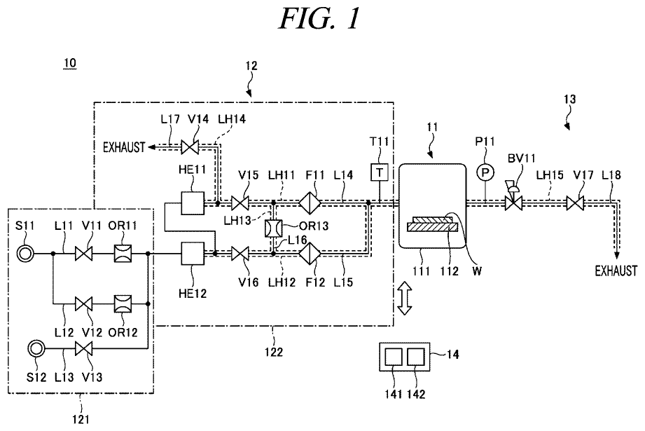

A substrate processing apparatus 10 according to a first exemplary embodiment will be described with reference to FIG. 1. FIG. 1 is a diagram illustrating the substrate processing apparatus 10 according to the first exemplary embodiment.

The substrate processing apparatus 10 is equipped with a processing device 11, a fluid supply system 12, a discharge device 13, and a controller 14.

The processing device 11 is equipped with a processing container 111 and a holding plate 112. The processing container 111 is a container in which a processing space capable of accommodating a substrate W having a diameter of, for example, 300 mm is formed. The substrate W may be, for example, a semiconductor wafer. The holding plate 112 is provided inside the processing container 111. The holding plate 112 horizontally holds the substrate W. The processing device 11 may be equipped with a pressure sensor configured to detect a pressure within the processing container 111 and a temperature sensor configured to detect a temperature within the processing container 111.

The fluid supply system 12 is equipped with a processing fluid supply 121 and a temperature adjusting device 122.

The processing fluid supply 121 is equipped with a processing fluid source S11, a first supply line L11, an opening/closing valve V11, an orifice OR11, a second supply line L12, an opening/closing valve V12, an orifice OR12, an inert gas source S12, a third supply line L13, and an opening/closing valve V13.

The processing fluid source S11 is a source of a processing fluid. The processing fluid may be, for example, liquid carbon dioxide (CO₂).

An upstream side of the first supply line L11 is connected to the processing fluid source S11, and a downstream side thereof is connected to the temperature adjusting device 122. The opening/closing valve V11 and the orifice OR11 are provided in sequence from the upstream side of the first supply line L11.

The opening/closing valve V11 is configured to switch ON and OFF of a flow of the processing fluid. In the open state, the opening/closing valve V11 allows the processing fluid to flow to the temperature adjusting device 122 on a downstream side. Also, in the closed state, the opening/closing valve V11 does not allow the processing fluid to flow to the temperature adjusting device 122 on the downstream side.

The orifice OR11 serves to adjust a pressure by reducing a flow velocity of the processing fluid in a liquid state. The orifice OR11 allows the pressure-adjusted processing fluid to flow to the temperature adjusting device 122 on the downstream side.

The second supply line L12 is provided in parallel with the first supply line L11. The second supply line L12 is branched off from the first supply line L11 on an upstream side of the opening/closing valve V11, and joins with the first supply line L11 on the downstream side of the orifice OR11. The opening/closing valve V12 and the orifice OR12 are provided in sequence from an upstream side of the second supply line L12.

The opening/closing valve V12 is configured to switch ON and OFF of a flow of the processing fluid. In the open state, the opening/closing valve V12 allows the processing fluid to flow to the temperature adjusting device 122 on the downstream side. Also, in the closed state, the opening/closing valve V12 does not allow the processing fluid to flow to the temperature adjusting device 122 on the downstream side.

The orifice OR12 serves to adjust a pressure by reducing a flow velocity of the processing fluid in a liquid state. The orifice OR12 allows the pressure-adjusted processing fluid to flow to the temperature adjusting device 122 on the downstream side.

The inert gas source S12 is a source of an inert gas. The inert gas may be, for example, a nitrogen (N₂) gas.

An upstream side of the third supply line L13 is connected to the inert gas source S12, and a downstream side thereof joins with the first supply line L11 on the downstream side of the orifice OR11. The opening/closing valve V13 is provided in the third supply line L13. A check valve, a filter, and the like may also be provided in the third supply line L13.

The opening/closing valve V13 is configured to switch ON and OFF of a flow of the inert gas. In the open state, the opening/closing valve V13 allows the inert gas to flow to the temperature adjusting device 122 on a downstream side. Also, in the closed state, the opening/closing valve V13 does not allow the inert gas to flow to the temperature adjusting device 122 on the downstream side.

The temperature adjusting device 122 is connected to the processing fluid supply 121 and the processing container 111. The temperature adjusting device 122 allows a temperature-adjusted fluid to flow inside the processing container 111. The fluid includes the processing fluid and the inert gas. The temperature adjusting device 122 is equipped with a first branch line L14, a second branch line L15, a bypass line L16, and a first discharge line L17.

A heating mechanism HE11, an opening/closing valve V15, a filter F11, and a temperature sensor T11 are provided in sequence from an upstream side of the first branch line L14. A line heater LH11 is provided on a downstream side of the heating mechanism HE11 in the first branch line L14. Sensors, such as a temperature sensor and a pressure sensor, may be provided at various positions in the first branch line L14.

A heating mechanism HE12, an opening/closing valve V16, and a filter F12 are provided in sequence from an upstream side of the second branch line L15. A line heater LH12 is provided on a downstream side of the heating mechanism HE12 in the second branch line L15. Sensors, such as a temperature sensor and a pressure sensor, may be provided at various positions in the second branch line L15.

The first branch line L14 is branched off from the second branch line L15 between the heating mechanism HE12 and the opening/closing valve V16. The second branch line L15 joins with the first branch line L14 at a position just before the processing container 111.

The heating mechanism HE11 and the heating mechanism HE12 are provided in series. The heating mechanism HE11 heats the fluid supplied from the processing fluid supply 121 to a first temperature, and supplies the fluid of the first temperature to the downstream side. The first temperature may be, for example, from 100 °C to 120 °C.

The opening/closing valve V15 is configured to switch ON and OFF of a flow of the fluid. In the open state, the opening/closing valve V15 allows the fluid to flow to the processing container 111 on a downstream side. Also, in the closed state, the opening/closing valve V15 does not allow the fluid to flow to the processing container 111 on the downstream side.

The filter F11 filters the fluid flowing inside the first branch line L14 to remove foreign matters contained in the fluid. Thus, it is possible to suppress the occurrence of particles on a surface of the substrate W during a processing of the substrate W using the fluid.

The temperature sensor T11 is provided on a downstream side of a junction between the first branch line L14 and the second branch line L15. For example, the temperature sensor T11 is provided at a position just before the processing container 111. The temperature sensor T11 detects a temperature of the fluid flowing inside the first branch line L14.

The line heater LH11 heats the first branch line L14 on the downstream side of the heating mechanism HE11. The line heater LH11 suppresses a decrease in temperature of the fluid, which has been heated to the first temperature by the heating mechanism HE11, when the fluid flows inside the first branch line L14.

The heating mechanism HE12 heats the fluid supplied from the processing fluid supply 121 to a second temperature, and supplies the fluid of the second temperature to the downstream side. The second temperature is lower than the first temperature. The second temperature may be, for example, from 80 °C to 90 °C.

The opening/closing valve V16 is configured to switch ON and OFF of a flow of the fluid. In the open state, the opening/closing valve V16 allows the fluid to flow to the processing container 111 on a downstream side. Also, in the closed state, the opening/closing valve V16 does not allow the fluid to flow to the processing container 111 on the downstream side.

The filter F12 filters the fluid flowing inside the second branch line L15 to remove foreign matters contained in the fluid. Thus, it is possible to suppress the occurrence of particles on the surface of the substrate W during the processing of the substrate W using the fluid.

The line heater LH12 heats the second branch line L15 on the downstream side of the heating mechanism HE12. The line heater LH12 suppresses a decrease in temperature of the fluid, which has been heated to the second temperature by the heating mechanism HE12, when the fluid flows inside the second branch line L15.

In the temperature adjusting device 122, the fluid, which has been heated to the second temperature by the heating mechanism HE12, is supplied into the processing container 111 through the second branch line L15 by closing the opening/closing valve V15 and opening the opening/closing valve V16. Also, the fluid, which has been heated to the second temperature by the heating mechanism HE12 and then heated to the first temperature by the heating mechanism HE11, is supplied into the processing container 111 through the first branch line L14 by closing the opening/closing valve V16 and opening the opening/closing valve V15. Since the opening/closing valve V15 and the opening/closing valve V16 are exclusively opened or closed, the temperature of the fluid flowing inside the processing container 111 can be changed. Further, when both the opening/closing valve V15 and the opening/closing valve V16 are opened, the fluid, which has been heated to the first temperature by the heating mechanism HE11, is mixed with the fluid, which has been heated to the second temperature by the heating mechanism HE12 and then supplied into the processing container 111. In this case, the fluid of an intermediate temperature between the first temperature and the second temperature can be supplied into the processing container 111. Thus, by controlling the opening and closing of the opening/closing valve V15 and the opening/closing valve V16, the temperature of the fluid flowing inside the processing container 111 can be changed in three stages.

The bypass line L16 communicates with a position between the opening/closing valve V15 and the filter F11 in the first branch line L14 and a position between the opening/closing valve V16 and the filter F12 in the second branch line L15. An orifice OR13 is provided in the bypass line L16. A line heater LH13 is provided in the bypass line L16. The bypass line L16, the orifice OR13, and the line heater LH13 may not be provided.

The orifice OR13 serves to adjust a pressure by reducing a flow velocity of the fluid flowing inside the bypass line L16.

The line heater LH13 heats the bypass line L16.

The first discharge line L17 discharges the fluid in the first branch line L14. The first discharge line L17 is branched off from the first branch line L14 between the heating mechanism HE11 and the opening/closing valve V15. An opening/closing valve V14 is provided in the first discharge line L17. A line heater LH14 is provided in the first discharge line L17. An orifice may be provided in the first discharge line L17.

The opening/closing valve V14 is configured to switch ON and OFF of a flow of the fluid. In the open state, the opening/closing valve V14 allows the fluid to flow to the first discharge line L17 on a downstream side. Also, in the closed state, the opening/closing valve V14 does not allow the fluid to flow to the first discharge line L17 on the downstream side.

The line heater LH14 heats the first discharge line L17.

The discharge device 13 is equipped with a discharge line L18. The discharge line L18 is connected to the processing container 111. A pressure sensor P11, a back pressure valve BV11, and an opening/closing valve V17 are provided in sequence from an upstream side of the discharge line L18. A line heater LH15 is provided in the discharge line L18. Sensors, such as a temperature sensor and a pressure sensor, may be provided at various positions in the discharge line L18.

The pressure sensor P11 detects a pressure of the fluid flowing inside the discharge line L18 at a position just after the processing container 111. Thus, the pressure sensor P11 can detect a pressure inside the processing container 111.

The back pressure valve BV11 is configured to maintain, when the primary side pressure exceeds a set pressure, a primary side pressure of the discharge line L18 to be the set pressure by adjusting the degree of valve opening and allowing the fluid to flow to a secondary side. For example, the set pressure of the back pressure valve BV11 is adjusted by the controller 14.

The opening/closing valve V17 is configured to switch ON and OFF of a flow of the fluid. In the open state, the opening/closing valve V17 allows the fluid to flow to the discharge line L18 on a downstream side. Also, in the closed state, the opening/closing valve V17 does not allow the fluid to flow to the discharge line L18 on the downstream side.

The line heater LH15 heats the discharge line L18.

The controller 14 receives measurement signals from various sensors (the temperature sensor T11, the pressure sensor P11, and the like) and transmits control signals to various functional elements. The control signals include, for example, opening/closing signals of the opening/closing valve V11 to the opening/closing valve V17, set pressure signals of the back pressure valve BV11, and temperature signals of the line heater LH11 to the line heater LH15. For example, the controller 14 controls the opening and closing of the opening/closing valve V11 and the opening/closing valve V12 depending on the processing state of the substrate W in the processing container 111 to change a flow rate of the fluid flowing inside the processing container 111. For example, the controller 14 controls the opening and closing of the opening/closing valve V15 and the opening/closing valve V16 depending on a processing state of the substrate W in the processing container 111 to change a temperature of the fluid flowing inside the processing container 111.

The controller 14 is, for example, a computer, and includes an operator 141 and a storage 142. The storage 142 stores a program that controls various processings performed in the substrate processing apparatus 10. The operator 141 controls operations of the substrate processing apparatus 10 by reading and executing the program stored in the storage 142. The program may be recorded in a computer-readable recording medium and installed from the recording medium to the storage 142 of the controller 14. The computer-readable recording medium may be, for example, a hard disk (HD), a flexible disk (FD), a compact disk (CD), a magnet optical disk (MO), or a memory card.

### Substrate Processing Method

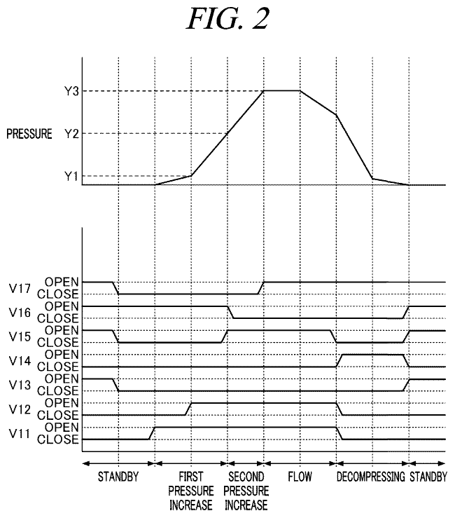

A substrate processing method performed by using the substrate processing apparatus 10 will be described with reference to FIG. 2 to FIG. 9. The substrate processing method described below is automatically performed under the control of the controller 14 based on a processing recipe and a control program that are stored in the storage 142.

FIG. 2 is a timing chart illustrating the substrate processing method according to the first exemplary embodiment. In FIG. 2, a lower diagram shows the opening/closing timing of the opening/closing valves V11, V12, V13, V14, V15, V16 and V17, and an upper diagram shows changes in detection value (pressure) of the pressure sensor P11 corresponding to the opening/closing timing.

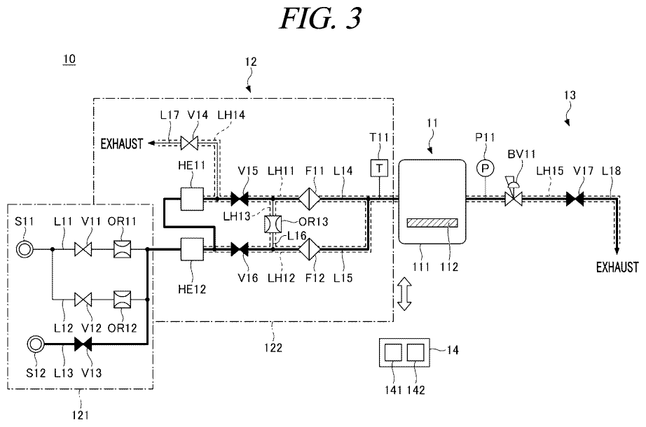

FIG. 3 to FIG. 9 are views illustrating the substrate processing method according to the first exemplary embodiment. In FIG. 3 to FIG. 9, the opening/closing valves in the open state are shown in black, while those in the closed state are shown in white. In FIG. 3 to FIG. 9, the line through which the fluid passes is represented by a bold solid line.

### <standby Process>

In a standby process, the inert gas is supplied to the processing device 11, the fluid supply system 12, and the discharge device 13. The inert gas may be, for example, a N₂ gas. Specifically, as illustrated in FIG. 3, the opening/closing valves V13, V15, V16 and V17 are opened, and the opening/closing valves V11, V12 and V14 are closed. Thus, the inert gas guided to the first branch line L14 from the inert gas source S12 is heated to the first temperature by the heating mechanism HE11 and supplied into the processing container 111. Also, the inert gas guided to the second branch line L15 from the inert gas source S12 is heated to the second temperature by the heating mechanism HE12 and supplied into the processing container 111. Therefore, the first branch line L14 and the second branch line L15 are purged and heated by the inert gas. Accordingly, a processing temperature of the substrate W after the standby process becomes approximately identical to processing temperatures of second and succeeding substrates W. As a result, it is possible to suppress non-uniformity of the processing temperature between the substrates W. In the standby process, the inert gas is discharged from the processing container 111 through the discharge line L18.

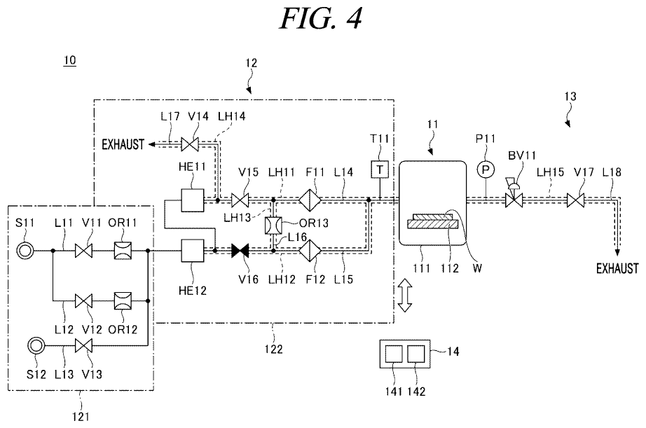

In the standby process, the substrate W is carried into the processing container 111. Specifically, as illustrated in FIG. 4, after the opening/closing valve V16 is opened and the opening/closing valves V11, V12, V13, V14, V15 and V17 are closed, the substrate W is carried into the processing container 111. That is, in a state where the inert gas is not supplied into the -14 processing container 111, the substrate W is carried into the processing container 111. However, the substrate W may be carried into the processing container 111 in a state where the inert gas is supplied into the processing container 111. The substrate W is subjected to a cleansing processing, and the substrate W with a surface on which isopropyl alcohol (IPA) is filled in a recess of a pattern is placed on the holding plate 112.

### First Pressure Increasing Process

A first pressure increasing process is performed after the standby process. In the first pressure increasing process, the processing fluid is supplied into the processing container 111 at a first flow rate and the second temperature to increase a pressure inside the processing container 111, and then the processing fluid is supplied into the processing container 111 at a second flow rate and the second temperature to further increase the pressure inside the processing container 111. That is, in the first pressure increasing process, the pressure increase is performed in two stages. The second flow rate may be higher than the first flow rate.

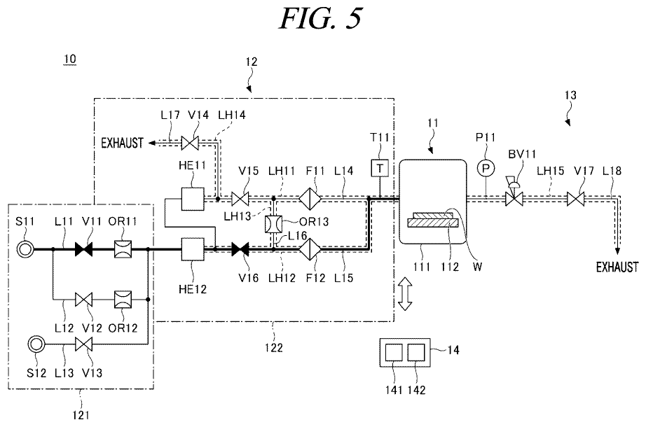

In the pressure increase with the first flow rate, the opening/closing valves V11 and V16 are opened and the opening/closing valves V12, V13, V14, V15 and V17 are closed as illustrated in FIG. 5. Thus, the processing fluid from the processing fluid source S11 is introduced into the temperature adjusting device 122 through the first supply line L11 and supplied into the processing container 111 through the second branch line L15. Therefore, the processing fluid is supplied into the processing container 111 at the first flow rate and the second temperature. Thus, the temperature of the substrate W is changed to the second temperature. In the pressure increase with the first flow rate, the opening/closing valve V17 is closed. Therefore, the processing fluid does not flow out of the processing container 111. Accordingly, the pressure inside the processing container 111 is gradually increased. In the pressure increase with the first flow rate, the processing fluid of which the flow velocity has been reduced by the orifice OR13 is introduced to the first branch line L14 from the second branch line L15 through the bypass line L16. Thus, it is possible to suppress backflow of the processing fluid from the junction between the first branch line L14 and the second branch line L15 at a position just before the processing container 111 toward the upstream side of the first branch line L14. Therefore, it is possible to suppress contamination caused by residues of IPA on a downstream side of the filter F11.

During the pressure increase with the first flow rate, the pressure inside the processing container 111 is detected by the pressure sensor P11, and the pressure increase with the first flow rate continues until the pressure inside the processing container 111 reaches a first pressure Y1. When the pressure inside the processing container 111 reaches the first pressure Y1, the pressure increase with the first flow rate is ended and the pressure increase with the second flow rate is begun.

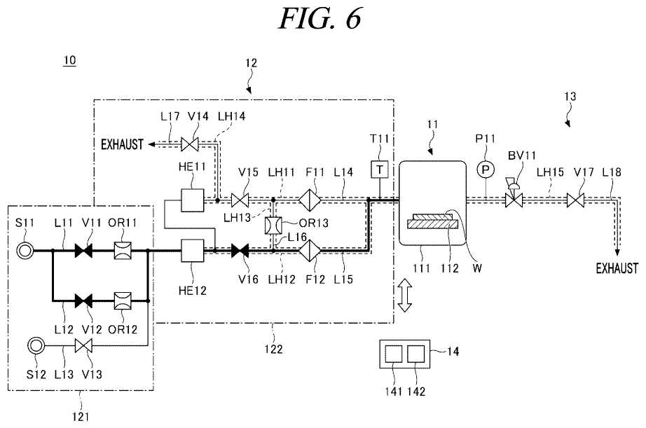

In the pressure increase with the second flow rate, the opening/closing valve V12 is opened as illustrated in FIG. 6. The states of the other opening/closing valves are the same as those shown in FIG. 5. Thus, the processing fluid from the processing fluid source S11 is introduced into the temperature adjusting device 122 through the second supply line L12 as well as the first supply line L11 and supplied into the processing container 111 through the second branch line L15. Therefore, the flow rate of the processing fluid supplied into the processing container 111 is increased to the second flow rate. In the pressure increase with the second flow rate, the opening/closing valve V17 is closed. Therefore, the processing fluid does not flow out of the processing container 111. Accordingly, the pressure inside the processing container 111 is gradually increased.

In the pressure increase with the second flow rate, the pressure of the processing fluid supplied into the processing container 111 is lower than a critical pressure. Therefore, the processing fluid in a gas state is supplied into the processing container 111. Then, as the processing fluid is filled into the processing container 111, the pressure inside the processing container 111 increases. When the pressure inside the processing container 111 exceeds the critical pressure, the processing fluid present in the processing container 111 is turned into a supercritical state.

In the pressure increase with the second flow rate, the processing fluid of which the flow velocity has been reduced by the orifice OR13 is introduced to the first branch line L14 from the second branch line L15 through the bypass line L16. Thus, it is possible to suppress the backflow of the processing fluid from the junction between the first branch line L14 and the second branch line L15 at the position just before the processing container 111 toward the upstream side of the first branch line L14. Therefore, it is possible to suppress the contamination caused by the residues of IPA on the downstream side of the filter F11.

During the pressure increase with the second flow rate, the pressure inside the processing container 111 is detected by the pressure sensor P11, and the pressure increase with the second flow rate continues until the pressure inside the processing container 111 reaches a second pressure Y2. When the pressure inside the processing container 111 reaches the second pressure Y2, the first pressure increasing process is ended and a second pressure increasing process is begun.

### Second Pressure Increasing Process

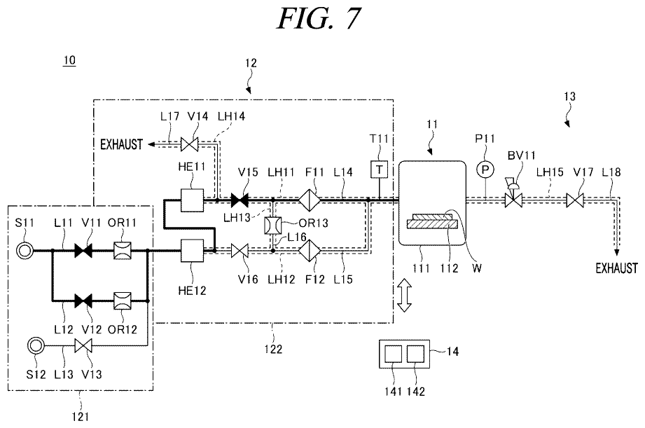

The second pressure increasing process is performed after the first pressure increasing process. In the second pressure increasing process, the processing fluid is supplied into the processing container 111 at the second flow rate and the first temperature to increase the pressure inside the processing container 111. Specifically, the opening/closing valves V11, V12 and V15 are opened and the opening/closing valves V13, V14, V16 and V17 are closed as illustrated in FIG. 7. Thus, the processing fluid from the processing fluid source S11 is introduced into the temperature adjusting device 122 through the first supply line L11 and the second supply line L12 to be supplied into the processing container 111 through the first branch line L14. Therefore, the processing fluid is supplied into the processing container 111 at the second flow rate and the first temperature. Thus, the temperature of the substrate W is rapidly changed to the first temperature.

In the second pressure increasing process, the processing fluid of which the flow velocity has been reduced by the orifice OR13 is introduced to the second branch line L15 from the first branch line L14 through the bypass line L16. Thus, it is possible to suppress the backflow of the processing fluid from the junction between the first branch line L14 and the second branch line L15 at the position just before the processing container 111 toward the upstream side of the second branch line L15. Therefore, it is possible to suppress the contamination caused by the residues of IPA on a downstream side of the filter F12.

During the second pressure increasing process, the pressure inside the processing container 111 is detected by the pressure sensor P11, and the second pressure increasing process continues until the pressure inside the processing container 111 reaches a third pressure Y3. When the pressure inside the processing container 111 reaches the third pressure Y3, the second pressure increasing process is ended and a flowing process is begun.

### Flowing Process

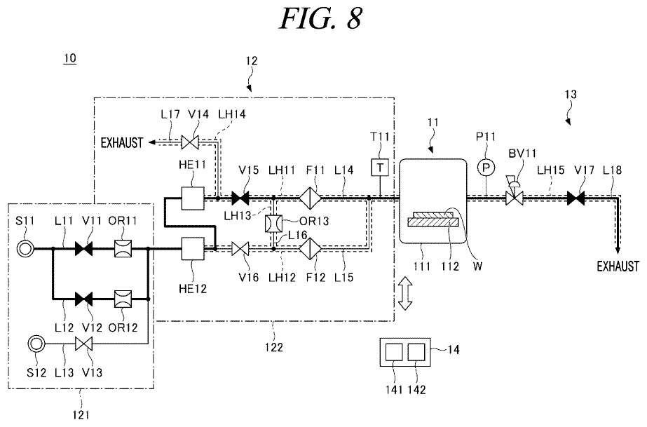

The flowing process is performed after the second pressure increasing process. In the flowing process, the processing fluid is supplied into the processing container 111 from the processing fluid source S11 at the second flow rate and the first temperature, and the IPA remaining in the recess of the pattern of the substrate W inside the processing container 111 is replaced with the processing fluid. Specifically, the opening/closing valves V11, V12, V15 and V17 are opened and the opening/closing valves V13, V14 and V16 are closed as illustrated in FIG. 8. Thus, the processing fluid from the processing fluid source S11 is introduced into the temperature adjusting device 122 through the first supply line L11 and the second supply line L12 to be supplied into the processing container 111 through the first branch line L14. The processing fluid supplied into the processing container 111 is discharged from the processing container 111 through the discharge line L18. Since the flowing process is performed, the replacement of IPA with the processing fluid in the recess of the pattern of the substrate W is facilitated.

In the flowing process, the processing fluid of which the flow velocity has been reduced by the orifice OR13 is introduced to the second branch line L15 from the first branch line L14 through the bypass line L16. Thus, it is possible to suppress backflow of the processing fluid from the junction between the first branch line L14 and the second branch line L15 at the position just before the processing container 111 toward the upstream side of the second branch line L15. Therefore, it is possible to suppress the contamination caused by the residues of IPA on the downstream side of the filter F12.

When the replacement of IPA with the processing fluid in the recess of the pattern is completed, the flowing process is ended and a decompressing process is begun.

### Decompressing Process

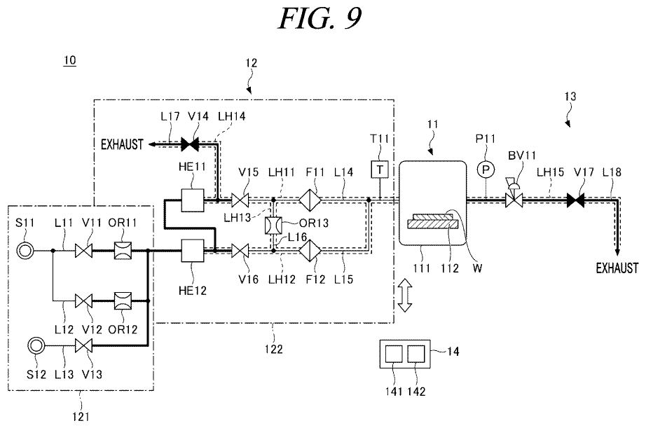

The decompressing process is performed after the flowing process. In the decompressing process, the processing fluid is discharged from the processing container 111. Specifically, the opening/closing valves V14 and V17 are opened and the opening/closing valves V11, V12, V13, V15 and V16 are closed as illustrated in FIG. 9. When the pressure inside the processing container 111 is lower than the critical pressure of the processing fluid due to the decompressing process, the processing fluid in the supercritical state evaporates and escapes the recess of the pattern. Thus, a drying processing of the substrate W is ended.

The standby process is begun again after the decompressing process. The processed substrate W is carried out of the processing container 111 after, for example, the standby process is begun. Specifically, after the decompressing process, the supply of the inert gas into the processing container 111 through the first branch line L14 and the second branch line L15 is started. Then, the substrate W is carried out of the processing container 111 in a state where the inert gas is supplied into the processing container 111. Even after the substrate W is carried out of the processing container 111, the supply of the inert gas into the processing container 111 continues. If the substrate W is carried out of the processing container 111 in a state where the inert gas is supplied into the processing container 111, the pressure inside the processing container 111 becomes a positive pressure. Thus, when the processing container 111 is opened, a gas flow is formed from the inside toward the outside of the processing container 111. Therefore, it is possible to remove residues present in the processing container 111 by discharging the residues to the outside of the processing container 111. However, when the substrate W is carried out of the processing container 111, the supply of the inert gas into the processing container 111 may be stopped.

According to the first exemplary embodiment described above, the fluid supply system 12 is equipped with the processing fluid supply 121 and the temperature adjusting device 122. The processing fluid supply 121 is equipped with a flow rate adjustment mechanism (the opening/closing valves V11 and V12, and the orifices OR11 and OR12) configured to adjust the flow rate of the processing fluid. The temperature adjusting device 122 is equipped with the first branch line L14 configured to allow the processing fluid of the first temperature to flow inside the processing container 111, and the second branch line L15 configured to allow the processing fluid of the second temperature to flow inside the processing container 111. Thus, the flow rate and the temperature of the processing fluid supplied into the processing container 111 can be individually controlled, and the processing fluid with the controlled flow rate and temperature can be supplied into the processing container 111. As a result, a process margin in the substrate processing method performed by using the substrate processing apparatus 10 can be expanded.

Also, according to the first exemplary embodiment, the temperature adjusting device 122 (the heating mechanisms HE11 and HE12) is provided on the downstream side of the first supply line L11 and the junction between the second supply line L12 and the third supply line L13. In this case, the inert gas from the inert gas source S12 is heated to the first temperature by the heating mechanism HE11 and then flows inside the first branch line L14. Therefore, in the first branch line L14 on the downstream side of the heating mechanism HE11, temperature uniformity along a flow direction of the fluid is improved. In this regard, when the inert gas of room temperature flows inside the first branch line L14, a temperature distribution along the flow direction of the fluid easily occurs in the first branch line L14 even if the first branch line L14 is heated by the line heater LH11.

Further, the inert gas from the inert gas source S12 is heated to the second temperature by the heating mechanism HE12 and then flows inside the second branch line L15. Therefore, in the second branch line L15 on the downstream side of the heating mechanism HE12, the temperature uniformity along the flow direction of the fluid is improved. In this regard, when the inert gas of room temperature flows inside the second branch line L15, the temperature distribution along the flow direction of the fluid easily occurs in the second branch line L15 even if the second branch line L15 is heated by the line heater LH12.

Furthermore, according to the first exemplary embodiment, the heated inert gas is supplied into the processing container 111 at the high flow rate through the first branch line L14 and the second branch line L15. Thus, the drying of IPA remaining in the first branch line L14, the second branch line L15, and the processing container 111 is facilitated.

Moreover, according to the first exemplary embodiment, in the standby process before the processing fluid from the processing fluid source S11 is supplied into the processing container 111 through the first branch line L14 and the second branch line L15, the heated inert gas flows inside the first branch line L14 and the second branch line L15. In this case, the first branch line L14 and the second branch line L15 are heated by the inert gas, and, thus, the processing temperature of the substrate W after the standby process becomes approximately identical to the processing temperatures of the second and succeeding substrates W. As a result, it is possible to suppress the non-uniformity of processing temperature between the substrates W.

### Second Exemplary Embodiment

### Substrate Processing Apparatus

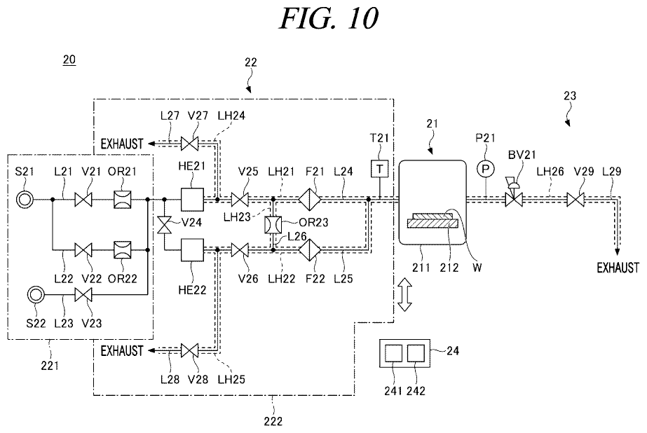

A substrate processing apparatus 20 according to a second exemplary embodiment will be described with reference to FIG. 10. FIG. 10 is a view illustrating the substrate processing apparatus 20 according to the second exemplary embodiment.

The substrate processing apparatus 20 is equipped with a processing device 21, a fluid supply system 22, a discharge device 23, and a controller 24.

The processing device 21 may be the same as the processing device 11. The processing device 21 is equipped with a processing container 211 and a holding plate 212.

-22 The fluid supply system 22 is equipped with a processing fluid supply 221 and a temperature adjusting device 222.

The processing fluid supply 221 may be the same as the processing fluid supply 121. The processing fluid supply 221 is equipped with a processing fluid source S21, a first supply line L21, an opening/closing valve V21, an orifice OR21, a second supply line L22, an opening/closing valve V22, an orifice OR22, an inert gas source S22, a third supply line L23, and an opening/closing valve V23.

The temperature adjusting device 222 is connected to the processing fluid supply 221 and the processing container 211. The temperature adjusting device 222 allows a temperature-adjusted fluid to flow inside the processing container 211. The fluid includes a processing fluid and an inert gas. The temperature adjusting device 222 is equipped with a first branch line L24, a second branch line L25, a bypass line L26, a first discharge line L27, and a second discharge line L28.

A heating mechanism HE21, an opening/closing valve V25, a filter F21, and a temperature sensor T21 are provided in sequence from an upstream side of the first branch line L24. A line heater LH21 is provided on a downstream side of the heating mechanism HE21 in the first branch line L24. Sensors, such as a temperature sensor and a pressure sensor, may be provided at various positions in the first branch line L24.

An opening/closing valve V24, a heating mechanism HE22, an opening/closing valve V26, and a filter F22 are provided in sequence from an upstream side of the second branch line L25. A line heater LH22 is provided on a downstream side of the heating mechanism HE22 in the second branch line L25. Sensors, such as a temperature sensor and a pressure sensor, may be provided at various positions in the second branch line L25.

The second branch line L25 is branched off from the first branch line L24 between the processing fluid supply 221 and the heating mechanism HE21. The second branch line L25 joins with the first branch line L24 at a position just before the processing container 211.

The heating mechanism HE21 is provided in parallel with the heating mechanism HE22. The heating mechanism HE21 heats the fluid supplied from the processing fluid supply 221 to a first temperature, and supplies the fluid of the first temperature to the downstream side. The first temperature may be, for example, from 100 °C to 120 °C.

The opening/closing valve V25 is configured to switch ON and OFF of a flow of the fluid. In the open state, the opening/closing valve V25 allows the fluid to flow to the processing container 211 on a downstream side. Also, in the closed state, the opening/closing valve V25 does not allow the fluid to flow to the processing container 211 on the downstream side.

The filter F21 filters the fluid flowing inside the first branch line L24 to remove foreign matters contained in the fluid. Thus, it is possible to suppress the occurrence of particles on the surface of the substrate W during a drying processing of the substrate W using the fluid.

The temperature sensor T21 is provided on a downstream side of a junction between the first branch line L24 and the second branch line L25. For example, the temperature sensor T21 is provided at a position just before the processing container 211. The temperature sensor T21 detects a temperature of the fluid flowing inside the first branch line L24.

The line heater LH21 heats the first branch line L24 on the downstream side of the heating mechanism HE21. The line heater LH21 suppresses a decrease in temperature of the fluid, which has been heated to the first temperature by the heating mechanism HE21, when the fluid flows inside the first branch line L24.

The opening/closing valve V24 is configured to switch ON and OFF of a flow of the fluid. In the open state, the opening/closing valve V24 allows the fluid to flow to the heating mechanism HE22 on a downstream side. Also, in the closed state, the opening/closing valve V24 does not allow the fluid to flow to the heating mechanism HE22 on the downstream side.

The heating mechanism HE22 heats the fluid supplied from the processing fluid supply 221 to a second temperature, and supplies the fluid of the second temperature to the downstream side. The second temperature is lower than the first temperature. The second temperature may be, for example, from 80 °C to 90 °C.

The opening/closing valve V26 is configured to switch ON and OFF of a flow of the fluid. In the open state, the opening/closing valve V26 allows the fluid to flow to the processing container 211 on a downstream side. Also, in the closed state, the opening/closing valve V26 does not allow the fluid to flow to the processing container 211 on the downstream side.

The filter F22 filters the fluid flowing inside the second branch line L25 to remove foreign matters contained in the fluid. Thus, it is possible to suppress the occurrence of particles on the surface of the substrate W during the drying processing of the substrate W using the fluid.

The line heater LH22 heats the second branch line L25 on the downstream side of the heating mechanism HE22. The line heater LH22 suppresses a decrease in temperature of the fluid, which has been heated to the second temperature by the heating mechanism HE22, when the fluid flows inside the second branch line L25.

In the temperature adjusting device 222, the fluid, which has been heated to the second temperature by the heating mechanism HE22, is supplied into the processing container 211 through the second branch line L25 by closing the opening/closing valve V25 and opening the opening/closing valve V26. Also, the fluid, which has been heated to the first temperature by the heating mechanism HE21, is supplied into the processing container 211 through the first branch line L24 by closing the opening/closing valve V26 and opening the opening/closing valve V25. Since the opening/closing valve V25 and the opening/closing valve V26 are exclusively opened or closed, the temperature of the fluid flowing inside the processing container 211 can be changed. Further, when both the opening/closing valve V25 and the opening/closing valve V26 are opened, the fluid, which has been heated to the first temperature by the heating mechanism HE21, is mixed with the fluid, which has been heated to the second temperature by the heating mechanism HE22 and then supplied into the processing container 211. In this case, the fluid of an intermediate temperature between the first temperature and the second temperature can be supplied into the processing container 211. Thus, by controlling the opening and closing of the opening/closing valve V25 and the opening/closing valve V26, the temperature of the fluid flowing inside the processing container 211 can be changed in three stages.

The bypass line L26 communicates with a position between the opening/closing valve V25 and the filter F21 in the first branch line L24 and a position between the opening/closing valve V26 and the filter F22 in the second branch line L25. An orifice OR23 is provided in the bypass line L26. A line heater LH23 is provided in the bypass line L26. The bypass line L26, the orifice OR23, and the line heater LH23 may not be provided.

The orifice OR23 serves to adjust a pressure by reducing a flow velocity of the fluid flowing inside the bypass line L26.

The line heater LH23 heats the bypass line L26.

The first discharge line L27 discharges the fluid in the first branch line L24. The first discharge line L27 is branched off from the first branch line L24 between the heating mechanism HE21 and the opening/closing valve V25. An opening/closing valve V27 is provided in the first discharge line L27. A line heater LH24 is provided in the first discharge line L27. An orifice may be provided in the first discharge line L27.

The opening/closing valve V27 is configured to switch ON and OFF of a flow of the fluid. In the open state, the opening/closing valve V27 allows the fluid to flow to the first discharge line L27 on a downstream side. Also, in the closed state, the opening/closing valve V27 does not allow the fluid to flow to the first discharge line L27 on the downstream side.

The line heater LH24 heats the first discharge line L27.

The second discharge line L28 discharges the fluid in the second branch line L25. The second discharge line L28 is branched off from the second branch line L25 between the heating mechanism HE22 and the opening/closing valve V26. An opening/closing valve V28 is provided in the second discharge line L28. A line heater LH25 is provided in the second discharge line L28. An orifice may be provided in the second discharge line L28.

The opening/closing valve V28 is configured to switch ON and OFF of a flow of the fluid. In the open state, the opening/closing valve V28 allows the fluid to flow to the second discharge line L28 on a downstream side. Also, in the closed state, the opening/closing valve V28 does not allow the fluid to flow to the second discharge line L28 on the downstream side.

The line heater LH25 heats the second discharge line L28.

The discharge device 23 is equipped with a discharge line L28. The discharge line L28 is connected to the processing container 211. A pressure sensor P21, a back pressure valve BV21, and an opening/closing valve V29 are provided in sequence from an upstream side of the discharge line L29. A line heater LH26 is provided in the discharge line L29. Sensors, such as a temperature sensor and a pressure sensor, may be provided at various positions in the discharge line L29.

The pressure sensor P21 detects a pressure of the fluid flowing inside the discharge line L29 at a position just after the processing container 211. Thus, the pressure sensor P21 can detect a pressure inside the processing container 211.

The back pressure valve BV21 is configured to maintain, when the primary side pressure exceeds a set pressure, a primary side pressure of the discharge line L29 to be the set pressure by adjusting the degree of valve opening and allowing the fluid to flow to a secondary side. For example, the set pressure of the back pressure valve BV21 is adjusted by the controller 24.

The opening/closing valve V29 is configured to switch ON and OFF of a flow of the fluid. In the open state, the opening/closing valve V29 allows the fluid to flow to the discharge line L29 on a downstream side. Also, in the closed state, the opening/closing valve V29 does not allow the fluid to flow to the discharge line L29 on the downstream side.

The line heater LH26 heats the discharge line L29.

The controller 24 receives measurement signals from various sensors (the temperature sensor T21, the pressure sensor P21, and the like) and transmits control signals to various functional elements. The control signals include, for example, opening/closing signals of the opening/closing valve V21 to the opening/closing valve V27, set pressure signals of the back pressure valve BV21, and temperature signals of the line heater LH21 to the line heater LH26. For example, the controller 24 controls the opening and closing of the opening/closing valve V21 and the opening/closing valve V22 depending on a processing state of the substrate W in the processing container 211 to change a flow rate of the fluid flowing inside the processing container 211. For example, the controller 24 controls the opening and closing of the opening/closing valve V25 and the opening/closing valve V26 depending on a processing state of the substrate W in the processing container 211 to change a temperature of the fluid flowing inside the processing container 211.

The controller 24 is, for example, a computer, and includes an operator 241 and a storage 242. The storage 242 stores a program that controls various processings performed in the substrate processing apparatus 20. The operator 241 controls operations of the substrate processing apparatus 20 by reading and executing the program stored in the storage 242. The program may be recorded in a computer-readable recording medium and installed from the recording medium to the storage 242 of the controller 24. The computer-readable recording medium may be, for example, a hard disk (HD), a flexible disk (FD), a compact disk (CD), a magnet optical disk (MO), or a memory card.

### Substrate Processing Method

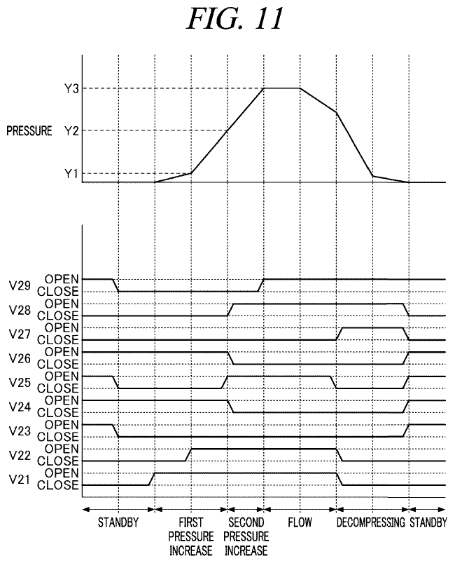

A substrate processing method performed by using the substrate processing apparatus 20 will be described with reference to FIG. 11 to FIG. 18. The substrate processing method described below is automatically performed under the control of the controller 24 based on a processing recipe and a control program that are stored in the storage 242.

FIG. 11 is a timing chart illustrating the substrate processing method according to the second exemplary embodiment. In FIG. 11, a lower diagram shows the opening/closing timing of the opening/closing valves V21, V22, V23, V24, V25, V26, V27, V28 and V29, and an upper diagram shows changes in detection value (pressure) of the pressure sensor P21 corresponding to the opening/closing timing.

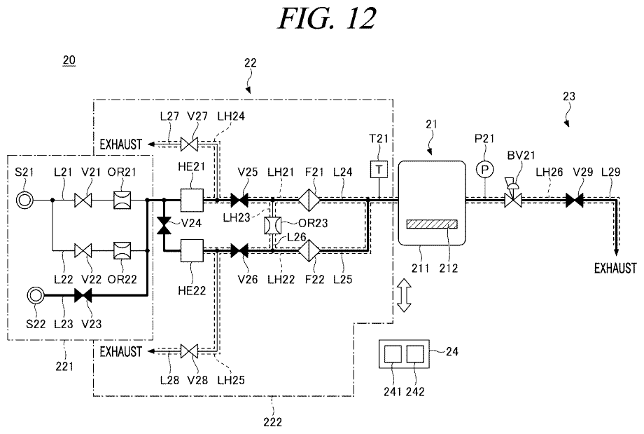

FIG. 12 to FIG. 18 are views illustrating the substrate processing method according to the second exemplary embodiment. In FIG. 12 to FIG. 18, the opening/closing valves in the open state are shown in black, while those in the closed state are shown in white. In FIG. 12 to FIG. 18, the line through which the fluid passes is represented by a bold solid line.

### Standby Process

In a standby process, the inert gas is supplied to the processing device 21, the fluid supply system 22, and the discharge device 23. The inert gas may be, for example, a N₂ gas. Specifically, as illustrated in FIG. 12, the opening/closing valves V23, V24, V25, V26 and V29 are opened, and the opening/closing valves V21, V22, V27 and V28 are closed. Thus, the inert gas guided to the first branch line L24 from the inert gas source S22 is heated to the first temperature by the heating mechanism HE21 and supplied into the processing container 211. Also, the inert gas guided to the second branch line L25 from the inert gas source S22 is heated to the second temperature by the heating mechanism HE22 and supplied into the processing container 211. Therefore, the first branch line L24 and the second branch line L25 are purged and heated by the inert gas. Accordingly, a processing temperature of the substrate W after the standby process becomes approximately identical to processing temperatures of second and succeeding substrates W. As a result, it is possible to suppress non-uniformity of processing temperature between the substrates W. In the standby process, the inert gas is discharged from the processing container 211 through the discharge line L29.

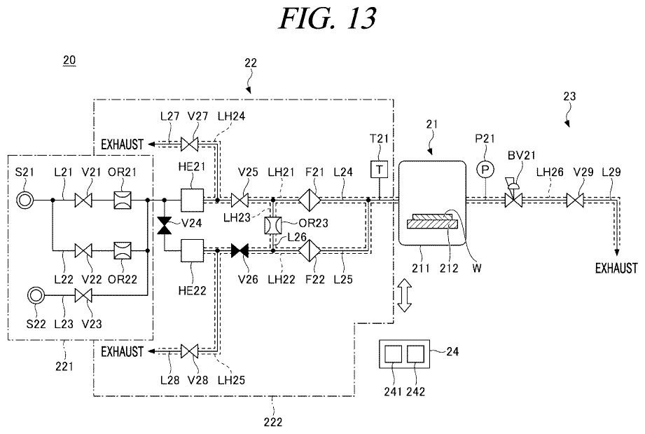

In the standby process, the substrate W is carried into the processing container 211. Specifically, as illustrated in FIG. 13, after the opening/closing valve V24 and V26 are opened and the opening/closing valves V21, V22, V23, V25, V27, V28 and V29 are closed, the substrate W is carried into the processing container 211. That is, in a state where the inert gas is not supplied into the processing container 211, the substrate W is carried into the processing container 211. However, the substrate W may be carried into the processing container 211 in a state where the inert gas is supplied into the processing container 211. The substrate W is subjected to a cleansing processing, and the substrate W with a surface on which IPA is filled in a recess of a pattern is placed on the holding plate 212.

### First Pressure Increasing Process

A first pressure increasing process is performed after the standby process. In first pressure increasing process, the processing fluid is supplied into the processing container 211 at a first flow rate and the second temperature to increase a pressure inside the processing container 211, and then the processing fluid is supplied into the processing container 211 at a second flow rate and the second temperature to further increase the pressure inside the processing container 211. That is, in the first pressure increasing process, the pressure increase is performed in two stages. The second flow rate may be higher than the first flow rate.

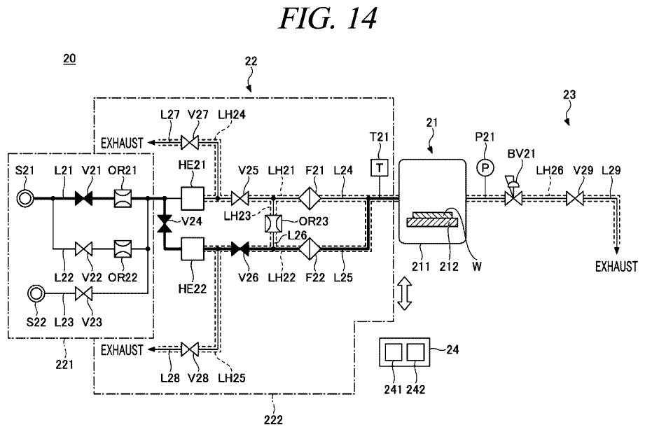

In the pressure increase with the first flow rate, the opening/closing valves V21, V24 and V26 are opened and the opening/closing valves V22, V23, V25, V27, V28 and V29 are closed as illustrated in FIG. 14. Thus, the processing fluid from the processing fluid source S21 is introduced into the temperature adjusting device 222 through the first supply line L21 and supplied into the processing container 211 through the second branch line L25. Therefore, the processing fluid is supplied into the processing container 211 at the first flow rate and the second temperature. Thus, the temperature of the substrate W is changed to the second temperature. In the pressure increase with the first flow rate, the opening/closing valve V29 is closed. Therefore, the processing fluid does not flow out of the processing container 211. Accordingly, the pressure inside the processing container 211 is gradually increased.

In the pressure increase with the first flow rate, the processing fluid of which the flow velocity has been reduced by the orifice OR23 is introduced to the first branch line L24 from the second branch line L25 through the bypass line L26. Thus, it is possible to suppress backflow of the processing fluid from the junction between the first branch line L24 and the second branch line L25 at a position just before the processing container 211 toward the upstream side of the first branch line L24. Therefore, it is possible to suppress contamination caused by residues of IPA on a downstream side of the filter F21.

During the pressure increase with the first flow rate, the pressure inside the processing container 211 is detected by the pressure sensor P21, and the pressure increase with the first flow rate continues until the pressure inside the processing container 211 reaches the first pressure Y1. When the pressure inside the processing container 211 reaches the first pressure Y1, the pressure increase with the first flow rate is ended and the pressure increase with the second flow rate is begun.

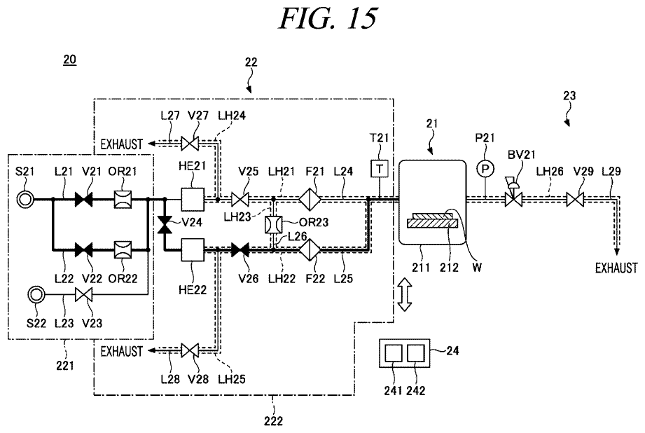

In the pressure increase with the second flow rate, the opening/closing valve V22 is opened as illustrated in FIG. 15. The states of the other opening/closing valves are the same as those shown in FIG. 14. Thus, the processing fluid from the processing fluid source S21 is introduced into the temperature adjusting device 222 through the second supply line L22 as well as the first supply line L21 and supplied into the processing container 211 through the second branch line L25. Therefore, the flow rate of the processing fluid supplied into the processing container 211 is increased to the second flow rate. In the pressure increase with the second flow rate, the opening/closing valve V29 is closed. Therefore, the processing fluid does not flow out of the processing container 211. Accordingly, the pressure inside the processing container 211 is gradually increased.

In the pressure increase with the second flow rate, the pressure of the processing fluid supplied into the processing container 211 is lower than a critical pressure. Therefore, the processing fluid in a gas state is supplied into the processing container 211. Then, as the processing fluid is filled into the processing container 211, the pressure inside the processing container 211 increases. When the pressure inside the processing container 211 exceeds the critical pressure, the processing fluid present in the processing container 211 is turned into a supercritical state.

In the pressure increase with the second flow rate, the processing fluid of which the flow velocity has been reduced by the orifice OR23 is introduced to the first branch line L24 from the second branch line L25 through the bypass line L26. Thus, it is possible to suppress the backflow of the processing fluid from the junction between the first branch line L24 and the second branch line L25 at the position just before the processing container 211 toward the upstream side of the first branch line L24. Therefore, it is possible to suppress the contamination caused by the residues of IPA on the downstream side of the filter F21.

During the pressure increase with the second flow rate, the pressure inside the processing container 211 is detected by the pressure sensor P21, and the pressure increase with the second flow rate continues until the pressure inside the processing container 211 reaches the second pressure Y2. When the pressure inside the processing container 211 reaches the second pressure Y2, the first pressure increasing process is ended and a second pressure increasing process is begun.

### Second Pressure Increasing Process

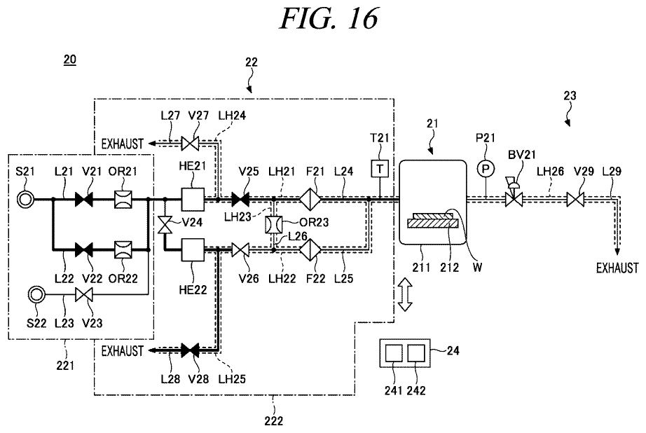

The second pressure increasing process is performed after the first pressure increasing process. In the second pressure increasing process, the processing fluid is supplied into the processing container 211 at the second flow rate and the first temperature to increase the pressure inside the processing container 211. Specifically, the opening/closing valves V21, V22, V25 and V28 are opened and the opening/closing valves V23, V24, V26, V27 and V29 are closed as illustrated in FIG. 16. Thus, the processing fluid from the processing fluid source S21 is introduced into the temperature adjusting device 222 through the first supply line L21 and the second supply line L22 and supplied into the processing container 211 through the first branch line L24. Therefore, the processing fluid is supplied into the processing container 211 at the second flow rate and the first temperature. Thus, the temperature of the substrate W is rapidly changed to the first temperature.

In the second pressure increasing process, the processing fluid of which the flow velocity has been reduced by the orifice OR23 is introduced to the second branch line L25 from the first branch line L24 through the bypass line L26. Thus, it is possible to suppress the backflow of the processing fluid from the junction between the first branch line L24 and the second branch line L25 at the position just before the processing container 211 toward the upstream side of the second branch line L25. Therefore, it is possible to suppress the contamination caused by the residues of IPA on a downstream side of the filter F22.

In the second pressure increasing process, the processing fluid inside the second branch line L25 is discharged to decompress the inside of the second branch line L25. A heat storage amount of the heating mechanism HE22, which is set to the second temperature lower than the first temperature, is small. Thus, when the pressure inside the second branch line L25 is decreased, the temperature of the heating mechanism HE22 is greatly decreased due to the pressure decrease, which requires time for the temperature of the heating mechanism HE22 to return to the second temperature. Thus, while the processing fluid flows inside the first branch line L24 in the second pressure increasing process, the opening/closing valves V24 and V26 are closed and the opening/closing valve V28 is opened. Therefore, it is possible to decompress the inside of the second branch line L25 and return the temperature of the heating mechanism HE22 34 to the second temperature. Since the second discharge line L28 and the opening/closing valve V28 are provided, it is possible to prepare the heating mechanism HE22 for the next substrate W while processing the substrate W inside the processing container 211.

During the second pressure increasing process, the pressure inside the processing container 211 is detected by the pressure sensor P21, and the second pressure increasing process continues until the pressure inside the processing container 211 reaches the third pressure Y3. When the pressure inside the processing container 211 reaches the third pressure Y3, the second pressure increasing process is ended and a flowing process is begun.

<flowing Process>

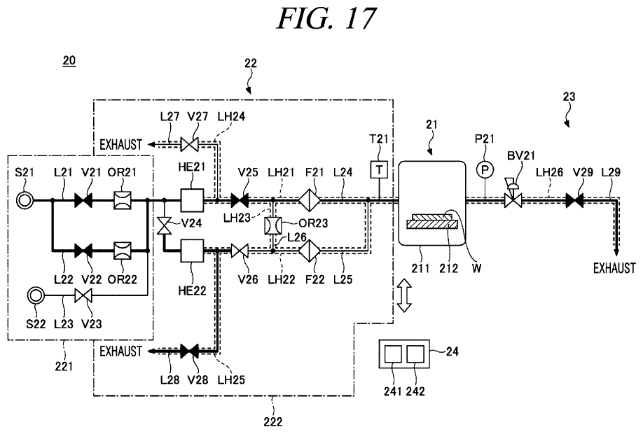

The flowing process is performed after the second pressure increasing process. In the flowing process, the processing fluid is supplied into the processing container 211 from the processing fluid source S21 at the second flow rate and the first temperature, and the IPA remaining in the recess of the pattern of the substrate W inside the processing container 211 is replaced with the processing fluid. Specifically, the opening/closing valves V21, V22, V25, V28 and V29 are opened and the opening/closing valves V23, V24, V26 and V27 are closed as illustrated in FIG. 17. Thus, the processing fluid from the processing fluid source S21 is introduced into the temperature adjusting device 222 through the first supply line L21 and the second supply line L22 and supplied into the processing container 211 through the first branch line L24. The processing fluid supplied into the processing container 211 is discharged from the processing container 211 through the discharge line L29. Since the flowing process is performed, the replacement of IPA with the processing fluid in the recess of the pattern of the substrate W is facilitated.

In the flowing process, the processing fluid of which the flow velocity has been reduced by the orifice OR23 is introduced to the second branch line L25 from the first branch line L24 through the bypass line L26. Thus, it is possible to suppress the backflow of the processing fluid from the junction between the first branch line L24 and the second branch line L25 at the position just before the processing container 211 toward the upstream side of the second branch line L25. Therefore, it is possible to suppress the contamination caused by the residues of IPA on the downstream side of the filter F22. Even in the flowing process, the decompression inside the second branch line L25 continues.

When the replacement of IPA with the processing fluid in the recess of the pattern is completed, the flowing process is ended and a decompressing process is begun.

### Decompressing Process

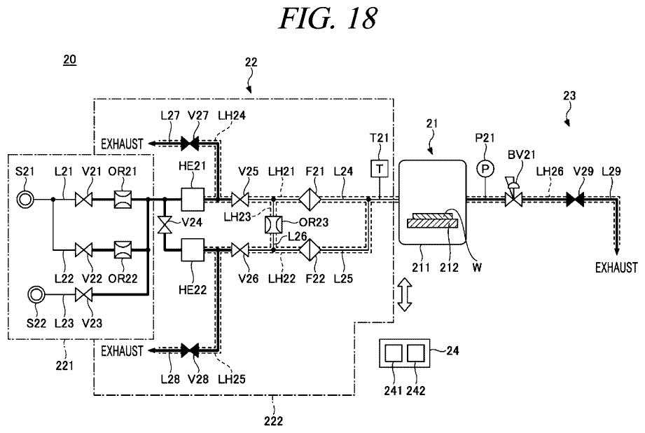

The decompressing process is performed after the flowing process. In the decompressing process, the processing fluid is discharged from the processing container 211. Specifically, the opening/closing valves V27, V28 and V29 are opened and the opening/closing valves V21, V22, V23, V24, V25 and V26 are closed as illustrated in FIG. 18. When the pressure inside the processing container 211 is lower than the critical pressure of the processing fluid due to the decompressing process, the processing fluid in the supercritical state evaporates and escapes the recess of the pattern. Thus, the drying processing of the substrate W is ended.

In the decompressing process, the processing fluid in the first branch line L24 is discharged through the first discharge line L27 and the processing fluid in the second branch line L25 is discharged through the second discharge line L28. That is, the processing fluid in the first branch line L24 and the processing fluid in the second branch line L25 are discharged through different discharge lines, respectively. Thus, it is possible to suppress mixing of the processing fluid of the first temperature and the processing fluid of the second temperature.

The standby process is begun after the decompressing process. The processed substrate W is carried out of the processing container 211 after, for example, the standby process is begun. Specifically, after the decompressing process, the supply of the inert gas into the processing container 211 through the first branch line L24 and the second branch line L25 is started. Then, the substrate W is carried out of the processing container 211 in a state where the inert gas is supplied into the processing container 211. Even after the substrate W is carried out of the processing container 211, the supply of the inert gas into the processing container 211 continues. If the substrate W is carried out of the processing container 211 in a state where the inert gas is supplied into the processing container 211, the pressure inside the processing container 211 becomes a positive pressure. Thus, when the processing container 211 is opened, a gas flow is formed from the inside toward the outside of the processing container 211. Therefore, it is possible to remove the residues present in the processing container 211 by discharging the residues to the outside of the processing container 211. However, when the substrate W is carried out of the processing container 211, the supply of the inert gas into the processing container 211 may be stopped.

According to the second exemplary embodiment described above, the fluid supply system 22 is equipped with the processing fluid supply 221 and the temperature adjusting device 222. The processing fluid supply 221 is equipped with a flow rate adjustment mechanism (the opening/closing valves V21 and V22, and the orifices OR21 and OR22) configured to adjust the flow rate of the processing fluid. The temperature adjusting device 222 is equipped with the first branch line L24 configured to allow the processing fluid of the first temperature to flow inside the processing container 211, and the second branch line L25 configured to allow the processing fluid of the second temperature to flow inside the processing container 211. Thus, the flow rate and the temperature of the processing fluid supplied into the processing container 211 can be individually controlled, and the processing fluid with the controlled flow rate and temperature can be supplied into the processing container 211. As a result, the process margin in the substrate processing method performed by using the substrate processing apparatus 10 can be expanded.

Also, according to the second exemplary embodiment, the temperature adjusting device 222 (the heating mechanisms HE21 and HE22) is provided on the downstream side of the first supply line L21 and the junction between the second supply line L22 and the third supply line L23. In this case, the inert gas from the inert gas source S22 is heated to the first temperature by the heating mechanism HE21 and then flows inside the first branch line L24. Therefore, in the first branch line L24 on the downstream side of the heating mechanism HE21, temperature uniformity along a flow direction of the fluid is improved. In this regard, when the inert gas of room temperature flows inside the first branch line L24, a temperature distribution along the flow direction of the fluid easily occurs in the first branch line L24 even if the first branch line L24 is heated by the line heater LH21.

Further, the inert gas from the inert gas source S22 is heated to the second temperature by the heating mechanism HE22 and then flows inside the second branch line L25. Therefore, in the second branch line L25 on the downstream side of the heating mechanism HE22, the temperature uniformity along the flow direction of the fluid is improved. In this regard, when the inert gas of room temperature flows inside the second branch line L25, the temperature distribution along the flow direction of the fluid easily occurs in the second branch line L25 even if the second branch line L25 is heated by the line heater LH22.

Furthermore, according to the second exemplary embodiment, the heated inert gas is supplied into the processing container 211 at the high flow rate through the first branch line L24 and the second branch line L25. Thus, the drying of IPA remaining in the first branch line L24, the second branch line L25, and the processing container 211 is facilitated.

Moreover, according to the second exemplary embodiment, in the standby process before the processing fluid from the processing fluid source S21 is supplied into the processing container 211 through the first branch line L24 and the second branch line L25, the heated inert gas flows inside the first branch line L24 and the second branch line L25. In this case, the first branch line L24 and the second branch line L25 are heated by the inert gas, and, thus, the processing temperature of the substrate W after the standby process becomes approximately identical to processing temperatures of the second and succeeding substrates W. As a result, it is possible to suppress the non-uniformity of processing temperature between the substrates W.

### First Modification Example of Second Exemplary Embodiment

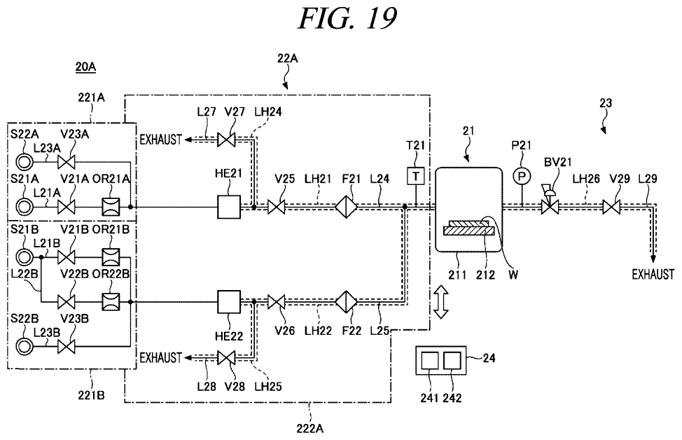

A substrate processing apparatus 20A according to a first modification example of the second exemplary embodiment will be described with reference to FIG. 19. FIG. 19 is a view illustrating the substrate processing apparatus 20A according to the first modification example of the second exemplary embodiment.

The substrate processing apparatus 20A is different from the substrate processing apparatus 20 in that each of the heating mechanism HE21 and the heating mechanism HE22 is connected to the processing fluid supply and the substrate processing apparatus 20A does not include the bypass line L26. The other components of the substrate processing apparatus 20A may be the same as those of the substrate processing apparatus 20. Hereinafter, the differences from the substrate processing apparatus 20 will be mainly described.

The substrate processing apparatus 20A is equipped with the processing device 21, a fluid supply system 22A, the discharge device 23, and the controller 24.

The fluid supply system 22A is equipped with a processing fluid supply 221A, a processing fluid supply 221B, and a temperature adjusting device 222A.

The processing fluid supply 221A is equipped with a processing fluid source S21A, a first supply line L21A, an opening/closing valve V21A, an orifice OR21A, an inert gas source S22A, a third supply line L23A, and an opening/closing valve V23A. The processing fluid source S21A, the first supply line L21A, the opening/closing valve V21A, the orifice OR21A, the inert gas source S22A, the third supply line L23A, and the opening/closing valve V23A may be the same as the processing fluid source S21, the first supply line L21, the opening/closing valve V21, the orifice OR21, the inert gas source S22, the third supply line L23, and the opening/closing valve V23, respectively.

The processing fluid supply 221B is equipped with a processing fluid source S21B, a first supply line L21B, an opening/closing valve V21B, an orifice OR21B, a second supply line L22B, an opening/closing valve V22B, an orifice OR22B, an inert gas source S22B, a third supply line L23B, and an opening/closing valve V23B. The processing fluid source S21B, the first supply line L21B, the opening/closing valve V21B, the orifice OR21B, the second supply line L22B, the opening/closing valve V22B, the orifice OR22B, the inert gas source S22B, the third supply line L23B, and the opening/closing valve V23B may be the same as the processing fluid source S21, the first supply line L21, the opening/closing valve V21, the orifice OR21, the second supply line L22, the opening/closing valve V22, the orifice OR22, the inert gas source S22, the third supply line L23, and the opening/closing valve V23, respectively.

The temperature adjusting device 222A is different from the temperature adjusting device 222 in that the heating mechanism HE21 is connected to the processing fluid supply 221A and the heating mechanism HE22 is connected to the processing fluid supply 221B.

In the substrate processing apparatus 20A, the processing fluid supplies 221A and 221B configured to supply the fluid to the temperature adjusting device 222A are switched by controlling the opening and closing of the opening/closing valves V21A, V23A, V21B, V22B and V23B. For example, the processing fluid is supplied from the processing fluid supply 221A to the first branch line L24 by opening the opening/closing valve V21A. For example, the inert gas is supplied from the processing fluid supply 221A to the first branch line L24 by opening the opening/closing valve V23A. For example, the processing fluid is supplied from the processing fluid supply 221B to the second branch line L25 by opening at least one of the opening/closing valve V21B and the opening/closing valve V22B. For example, the inert gas is supplied from the processing fluid supply 221B to the second branch line L25 by opening the opening/closing valve V23B. For example, in the substrate processing apparatus 20A, the processing fluid supplies 221A and 221B configured to supply the fluid to the temperature adjusting device 222A are switched depending on a process to be performed.

### Second Modification Example of Second Exemplary Embodiment

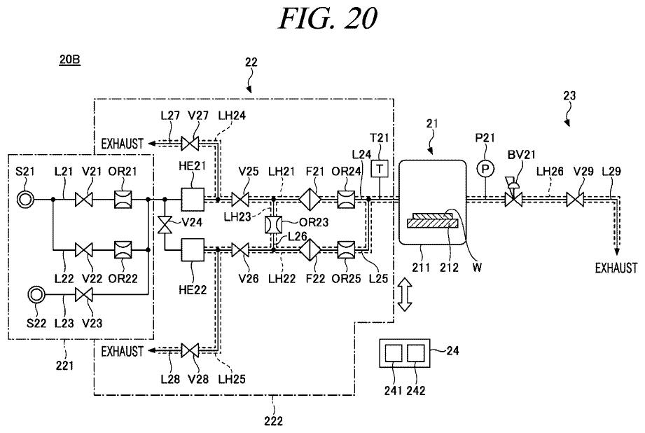

A substrate processing apparatus 20B according to a second modification example of the second exemplary embodiment will be described with reference to FIG. 20. FIG. 20 is a view illustrating the substrate processing apparatus 20B according to the second modification example of the second exemplary embodiment.

The substrate processing apparatus 20B is different from the substrate processing apparatus 20 in that the substrate processing apparatus 20B includes an orifice OR24 and an orifice OR25.

The orifice OR24 is provided in the first branch line L24 on the downstream side of the filter F21 and on the upstream side of the junction between the first branch line L24 and the second branch line L25. The orifice OR24 has a greater pressure loss than the orifice OR23. In other words, the orifice OR24 has a smaller flow path area than the orifice OR23.

The orifice OR25 is provided in the second branch line L25 on the downstream side of the filter F22 and the upstream side of the junction between the first branch line L24 and the second branch line L25. The orifice OR25 has a greater pressure loss than the orifice OR23. In other words, the orifice OR25 has a smaller flow path area than the orifice OR23.

In the substrate processing apparatus 20B, the fluid, which has been heated to the second temperature by the heating mechanism HE22, is supplied into the processing container 211 through the second branch line L25 by closing the opening/closing valve V25 and opening the opening/closing valve V26. In this case, the fluid of which the flow velocity has been reduced by the orifice OR23 is introduced to the first branch line L24 from the second branch line L25 through the bypass line L26. Thus, it is possible to suppress the backflow of the fluid from the processing container 211 toward the first branch line L24. Therefore, it is possible to suppress the contamination caused by the residues of IPA in the first branch line L24. Also, the orifice OR24 with the greater pressure loss than the orifice OR23 is provided in the first branch line L24 on the downstream side of the filter F21. In this case, the pressure inside the second branch line L25 between the opening/closing valve V26 and the filter F22, the pressure inside the first branch line L24 on an upstream side of the orifice OR24, and the pressure inside the first branch line L24 on the downstream side of the orifice OR24 decrease in this sequence. Therefore, it is possible to further suppress the backflow of the fluid from the processing container 211 toward the first branch line L24.

Further, the fluid, which has been heated to the first temperature by the heating mechanism HE21, is supplied into the processing container 211 through the first branch line L24 by closing the opening/closing valve V26 and opening the opening/closing valve V25. In this case, the fluid of which the flow velocity has been reduced by the orifice OR23 is introduced to the second branch line L25 from the first branch line L24 through the bypass line L26. Thus, it is possible to suppress the backflow of the fluid from the processing container 211 toward the second branch line L25. Therefore, it is possible to suppress the contamination caused by the residues of IPA in the second branch line L25. Furthermore, the orifice OR25 with the greater pressure loss than the orifice OR23 is provided in the second branch line L25 on the downstream side of the filter F22. In this case, the pressure inside the first branch line L24 between the opening/closing valve V25 and the filter F21, the pressure inside the second branch line L25 on the upstream side of the orifice OR25, and the pressure inside the second branch line L25 on the downstream side of the orifice OR25 decrease in this sequence. Therefore, it is possible to further suppress the backflow of the fluid from the processing container 211 toward the second branch line L25.

### Third Exemplary Embodiment

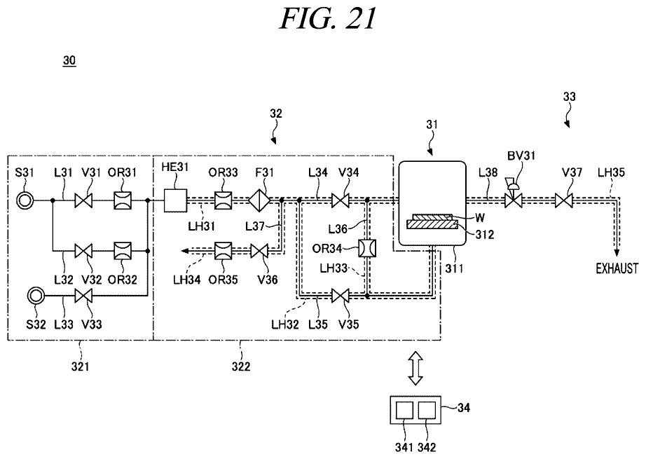

A substrate processing apparatus 30 according to a third exemplary embodiment will be described with reference to FIG. 21. FIG. 21 is a view illustrating the substrate processing apparatus 30 according to the third exemplary embodiment.

The substrate processing apparatus 30 is equipped with a processing device 31, a fluid supply system 32, a discharge device 33, and a controller 34.

The processing device 31 may be the same as the processing device 11. The processing device 31 is equipped with a processing container 311 and a holding plate 312.

The fluid supply system 32 is equipped with a processing fluid supply 321 and a temperature adjusting device 322.

The processing fluid supply 321 may be the same as the processing fluid supply 121. The processing fluid supply 321 is equipped with a processing fluid source S31, a first supply line L31, an opening/closing valve V31, an orifice OR31, a second supply line L32, an opening/closing valve V32, an orifice OR32, an inert gas source S32, a third supply line L33, and an opening/closing valve V33.

The temperature adjusting device 322 is connected to the processing fluid supply 321 and the processing container 311. The temperature adjusting device 322 allows a temperature-adjusted fluid to flow inside the processing container 311. The fluid includes a processing fluid and an inert gas. The temperature adjusting device 322 is equipped with a first line L34, a second line L35, a bypass line L36, and a first discharge line L37.

The first line L34 is connected to a side of the processing container 311. The first line L34 supplies the fluid from the side of the processing container 311 toward the substrate W. A heating mechanism HE31, an orifice OR33, a filter F31, and an opening/closing valve V34 are provided in sequence from an upstream side of the first line L34. A line heater LH31 is provided on a downstream side of the heating mechanism HE31 in the first line L34. Sensors, such as a temperature sensor and a pressure sensor, may be provided at various positions in the first line L34.

The heating mechanism HE31 heats the fluid supplied from the processing fluid supply 321 to a predetermined temperature, and supplies the fluid of the predetermined temperature to the downstream side.

The orifice OR33 serves to adjust a pressure by reducing a flow velocity of the fluid flowing inside the first line L34.

The filter F31 filters the fluid flowing inside the first line L34 to remove foreign matters contained in the fluid. Thus, it is possible to suppress the occurrence of particles on the surface of the substrate W during a drying processing of the substrate W using the fluid.

The opening/closing valve V34 is configured to switch ON and OFF of a flow of the fluid. In the open state, the opening/closing valve V34 allows the fluid to flow to the processing container 311 on a downstream side. Also, in the closed state, the opening/closing valve V34 does not allow the fluid to flow to the processing container 311 on the downstream side.

The line heater LH31 heats the first line L34 on the downstream side of the heating mechanism HE31. The line heater LH31 suppresses a decrease in temperature of the fluid, which has been heated to the predetermined temperature by the heating mechanism HE31, when the fluid flows inside the first line L34.

The second line L35 is branched off from the first line L34 between the filter F31 and the opening/closing valve V34. The second line L35 is connected to a bottom of the processing container 311. The second line L35 supplies the fluid from the bottom of the processing container 311 toward the substrate W. An opening/closing valve V35 is provided in the second line L35. A line heater LH32 is provided in the second line L35. Sensors, such as a temperature sensor and a pressure sensor, may be provided at various positions in the second line L35.

The opening/closing valve V35 is configured to switch ON and OFF of a flow of the fluid. In the open state, the opening/closing valve V35 allows the fluid to flow to the processing container 311 on a downstream side. Also, in the closed state, the opening/closing valve V35 does not allow the fluid to flow to the processing container 311 on the downstream side.

The line heater LH32 heats the second line L35. The line heater LH32 suppresses a decrease in temperature of the fluid, which has been heated to the predetermined temperature by the heating mechanism HE31, when the fluid flows inside the second line L35.

The bypass line L36 communicates with a position on a downstream side of the opening/closing valve V34 in the first line L34 and a position on a downstream side of the opening/closing valve V35 in the second line L35. An orifice OR34 is provided in the bypass line L36. A line heater LH33 is provided in the bypass line L36.

The orifice OR34 serves to adjust a pressure by reducing a flow velocity of the fluid flowing inside the bypass line L36.

The line heater LH33 heats the bypass line L36.

In the temperature adjusting device 322, the fluid, which has been heated to the predetermined temperature by the heating mechanism HE31, is supplied into the processing container 311 from the bottom of the processing container 311 through the second line L35 by closing the opening/closing valve V34 and opening the opening/closing valve V35. In this case, the fluid of which the flow velocity has been reduced by the orifice OR34 is introduced to the first line L34 from the second line L35 through the bypass line L36. Thus, it is possible to suppress backflow of the fluid from the processing container 311 toward the first line L34. Therefore, it is possible to suppress contamination caused by residues of IPA in the first line L34.

Further, the fluid, which has been heated to the predetermined temperature by the heating mechanism HE31, is supplied into the processing container 311 from the side of the processing container 311 through the first line L34 by closing the opening/closing valve V35 and opening the opening/closing valve V34. In this case, the fluid of which the flow velocity has been reduced by the orifice OR34 is introduced to the second line L35 from the first line L34 through the bypass line L36. Thus, it is possible to suppress the backflow of the fluid from the processing container 311 toward the second line L35. Therefore, it is possible to suppress the contamination caused by the residues of IPA in the second line L35.

The first discharge line L37 discharges the fluid in the first line L34. The first discharge line L37 is branched off from the first line L34 between the filter F31 and the opening/closing valve V34. An opening/closing valve V36 and an orifice OR35 are provided in sequence from an upstream side of the first discharge line L37. A line heater LH34 is provided in the first discharge line L37. The orifice 35 may not be provided.

The opening/closing valve V36 is configured to switch ON and OFF of a flow of the fluid. In the open state, the opening/closing valve V36 allows the fluid to flow to the first discharge line L37 on a downstream side. Also, in the closed state, the opening/closing valve V36 does not allow the fluid to flow to the first discharge line L37 on the downstream side.

The orifice OR35 serves to adjust a pressure by reducing a flow velocity of the fluid flowing inside the first discharge line L37.

The line heater LH34 heats the first discharge line L37.

The discharge device 33 is equipped with a discharge line L38. The discharge line L38 is connected to the processing container 311. A back pressure valve BV31 and an opening/closing valve V37 are provided in sequence from an upstream side of the discharge line L38. A line heater LH35 is provided in the discharge line L38. Sensors, such as a temperature sensor and a pressure sensor, may be provided at various positions in the discharge line L38.

The back pressure valve BV31, the opening/closing valve V37, and the line heater LH35 may be the same as the back pressure valve BV11, the opening/closing valve V17, and the line heater LH15, respectively.

Like the controller 14, the controller 34 receives measurement signals from various sensors and transmits control signals to various functional elements. The controller 34 is, for example, a computer, and includes an operator 341 and a storage 342. The operator 341 and the storage 342 may be the same as the operator 141 and the storage 142, respectively.

### Fourth Exemplary Embodiment

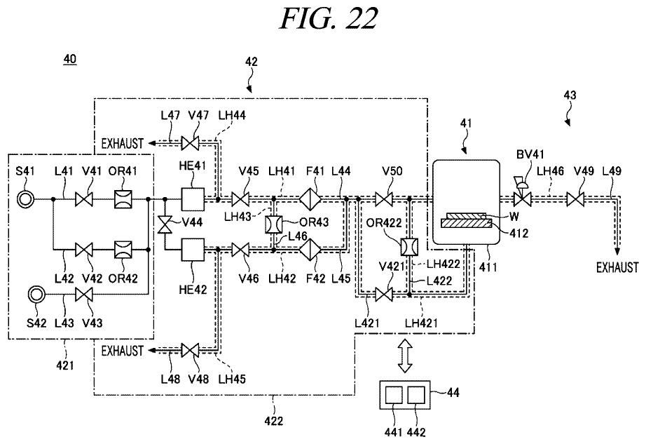

A substrate processing apparatus 40 according to a fourth exemplary embodiment will be described with reference to FIG. 22. FIG. 22 is a view illustrating the substrate processing apparatus 40 according to the fourth exemplary embodiment.

The substrate processing apparatus 40 is equipped with a processing device 41, a fluid supply system 42, a discharge device 43, and a controller 44.

The processing device 41 may be the same as the processing device 11. The processing device 41 is equipped with a processing container 411 and a holding plate 412.

The fluid supply system 42 is equipped with a processing fluid supply 421 and a temperature adjusting device 422.

The processing fluid supply 421 may be the same as the processing fluid supply 121. The processing fluid supply 421 is equipped with a processing fluid source S41, a first supply line L41, an opening/closing valve V41, an orifice OR41, a second supply line L42, an opening/closing valve V42, an orifice OR42, an inert gas source S42, a third supply line L43, and an opening/closing valve V43.

The temperature adjusting device 422 is connected to the processing fluid supply 421 and the processing container 411. The temperature adjusting device 422 allows a temperature-adjusted fluid to flow inside the processing container 411. The fluid includes a processing fluid and an inert gas. The temperature adjusting device 422 is equipped with a first branch line L44, a second branch line L45, a first bypass line L46, a first discharge line L47, a second discharge line L48, a third branch line L421, and a second bypass line L422.

The first branch line L44 is connected to a side of the processing container 411. The first branch line L44 supplies the fluid from the side of the processing container 411 toward the substrate W. A heating mechanism HE41, an opening/closing valve V45, a filter F41, and an opening/closing valve V50 are provided in sequence from an upstream side of the first branch line L44. A line heater LH41 is provided on a downstream side of the heating mechanism HE41 in the first branch line L44. Sensors, such as a temperature sensor and a pressure sensor, may be provided at various positions in the first branch line L44.

The heating mechanism HE41 is provided in parallel with a heating mechanism HE42. The heating mechanism HE41 heats the fluid supplied from the processing fluid supply 421 to a first temperature, and supplies the fluid of the first temperature to the downstream side. The first temperature may be, for example, from 100 °C to 120 °C.

The opening/closing valve V45 is configured to switch ON and OFF of a flow of the fluid. In the open state, the opening/closing valve V45 allows the fluid to flow to the filter F41 on a downstream side. Also, in the closed state, the opening/closing valve V45 does not allow the fluid to flow to the filter F41 on the downstream side.

The filter F41 filters the fluid flowing inside the first branch line L44 to remove foreign matters contained in the fluid. Thus, it is possible to suppress the occurrence of particles on the surface of the substrate W during a drying processing of the substrate W using the fluid.

The opening/closing valve V50 is configured to switch ON and OFF of a flow of the fluid. In the open state, the opening/closing valve V50 allows the fluid to flow to the processing container 411 on a downstream side. Also, in the closed state, the opening/closing valve V50 does not allow the fluid to flow to the processing container 411 on the downstream side.

The line heater LH41 heats the first branch line L44 on the downstream side of the heating mechanism HE41. The line heater LH41 suppresses a decrease in temperature of the fluid, which has been heated to the first temperature by the heating mechanism HE41, when the fluid flows inside the first branch line L44.

The second branch line L45 is branched off from the first branch line L44 between the processing fluid supply 421 and the heating mechanism HE41. The second branch line L45 joins with the first branch line L44 between the filter F41 and the opening/closing valve V50.

An opening/closing valve V44, the heating mechanism HE42, an opening/closing valve V46, and a filter F42 are provided in sequence from an upstream side of the second branch line L45. A line heater LH42 is provided on a downstream side of the heating mechanism HE42 in the second branch line L45. Sensors, such as a temperature sensor and a pressure sensor, may be provided at various positions in the second branch line L45.

The opening/closing valve V44 is configured to switch ON and OFF of a flow of the fluid. In the open state, the opening/closing valve V44 allows the fluid to flow to the heating mechanism HE42 on a downstream side. Also, in the closed state, the opening/closing valve V44 does not allow the fluid to flow to the heating mechanism HE42 on the downstream side.

The heating mechanism HE42 heats the fluid supplied from the processing fluid supply 421 to a second temperature, and supplies the fluid of the second temperature to the downstream side. The second temperature is lower than the first temperature. The second temperature may be, for example, from 80 °C to 90 °C.

The opening/closing valve V46 is configured to switch ON and OFF of a flow of the fluid. In the open state, the opening/closing valve V46 allows the fluid to flow to the filter F42 on a downstream side. Also, in the closed state, the opening/closing valve V46 does not allow the fluid to flow to the filter F42 on the downstream side.

The filter F42 filters the fluid flowing inside the second branch line L45 to remove the foreign matters contained in the fluid. Thus, it is possible to suppress the occurrence of particles on the surface of the substrate W during the drying processing of the substrate W using the fluid.

The line heater LH42 heats the second branch line L45 on the downstream side of the heating mechanism HE42. The line heater LH42 suppresses the decrease in temperature of the fluid, which has been heated to the second temperature by the heating mechanism HE42, when the fluid flows inside the second branch line L45.

The first bypass line L46 communicates with a position between the opening/closing valve V45 and the filter F41 in the first branch line L44 and a position between the opening/closing valve V46 and the filter F42 in the second branch line L45. An orifice OR43 is provided in the first bypass line L46. A line heater LH43 is provided in the first bypass line L46. The first bypass line L46, the orifice OR43, and the line heater LH43 may not be provided.

The orifice OR43 serves to adjust a pressure by reducing a flow velocity of the fluid flowing inside the first bypass line L46.

The line heater LH43 heats the first bypass line L46.

In the temperature adjusting device 422, the fluid, which has been heated to the second temperature by the heating mechanism HE42, is supplied into the processing container 411 through the second branch line L45 by closing the opening/closing valve V45 and opening the -51 opening/closing valve V46. In this case, the fluid of which the flow velocity has been reduced by the orifice OR43 is introduced to the first branch line L44 from the second branch line L45 through the first bypass line L46. Thus, it is possible to suppress backflow of the fluid from a junction between the first branch line L44 and the second branch line L45 toward an upstream side of the second branch line L44. Therefore, it is possible to suppress contamination in the first branch line L44, the filter F41, and the like.

Further, the fluid, which has been heated to the first temperature by the heating mechanism HE41, is supplied into the processing container 411 through the first branch line L44 by closing the opening/closing valve V46 and opening the opening/closing valve V45. In this case, the fluid of which the flow velocity has been reduced by the orifice OR43 is introduced to the second branch line L45 from the first branch line L44 through the first bypass line L46 Thus, it is possible to suppress the backflow of the fluid from the junction between the first branch line L44 and the second branch line L45 toward the upstream side of the second branch line L45. Therefore, it is possible to suppress the contamination in the second branch line L45, the filter F42, and the like.

Since the opening/closing valve V45 and the opening/closing valve V46 are exclusively opened or closed, the temperature of the fluid flowing inside the processing container 411 can be changed. Further, when both the opening/closing valve V45 and the opening/closing valve V46 are opened, the fluid, which has been heated to the first temperature by the heating mechanism HE41, is mixed with the fluid, which has been heated to the second temperature by the heating mechanism HE42 and then supplied into the processing container 411. In this case, the fluid of an intermediate temperature between the first temperature and the second temperature can be supplied into the processing container 411. Thus, by controlling the opening -52 and closing of the opening/closing valve V45 and the opening/closing valve V46, the temperature of the fluid flowing inside the processing container 411 can be changed in three stages.

The first discharge line L47 discharges the fluid in the first branch line L44. The first discharge line L47 is branched off from the first branch line L44 between the heating mechanism HE41 and the opening/closing valve V45. An opening/closing valve V47 is provided in the first discharge line L47. A line heater LH44 is provided in the first discharge line L47. An orifice may be provided in the first discharge line L47.

The opening/closing valve V47 is configured to switch ON and OFF of a flow of the fluid. In the open state, the opening/closing valve V47 allows the fluid to flow to the first discharge line L47 on a downstream side. Also, in the closed state, the opening/closing valve V47 does not allow the fluid to flow to the first discharge line L47 on the downstream side.

The line heater LH44 heats the first discharge line L47.

The second discharge line L48 discharges the fluid in the second branch line L45. The second discharge line L48 is branched off from the second branch line L45 between the heating mechanism HE42 and the opening/closing valve V46. An opening/closing valve V48 is provided in the second discharge line L48. A line heater LH45 is provided in the second discharge line L48. An orifice may be provided in the second discharge line L48.

The opening/closing valve V48 is configured to switch ON and OFF of a flow of the fluid. In the open state, the opening/closing valve V48 allows the fluid to flow to the second discharge line L48 on a downstream side. Also, in the closed state, the opening/closing valve V48 does not allow the fluid to flow to the second discharge line L48 on the downstream side.

The line heater LH45 heats the second discharge line L48.

The third branch line L421 is branched off from the first branch line L44 between the filter F41 and the opening/closing valve V50. The third branch line L421 is connected to a bottom of the processing container 411. The third branch line L421 supplies the fluid from the bottom of the processing container 411 toward the substrate W.

An opening/closing valve V421 is provided in the third branch line L421. A line heater LH421 is provided in the third branch line L421. Sensors, such as a temperature sensor and a pressure sensor, may be provided at various positions in the third branch line L421.

The opening/closing valve V421 is configured to switch ON and OFF of a flow of the fluid. In the open state, the opening/closing valve V421 allows the fluid to flow to the processing container 411 on a downstream side. Also, in the closed state, the opening/closing valve V421 does not allow the fluid to flow to the processing container 411 on the downstream side.

The line heater LH421 heats the third branch line L421. The line heater LH421 suppresses a decrease in temperature of the fluid, which has been heated to the first temperature by the heating mechanism HE41, and the fluid, which has been heated to the second temperature by the heating mechanism HE42, when the fluid flows inside the third branch line L421.

The second bypass line L422 communicates with a position on a downstream side of the opening/closing valve V50 in the first branch line L44 and a position on a downstream side of the opening/closing valve V421 in the third branch line L421. An orifice OR422 is provided in the second bypass line L422. A line heater LH422 is provided in the second bypass line L422.

The orifice OR422 serves to adjust a pressure by reducing a flow velocity of the fluid flowing inside the second bypass line L422.

The line heater LH422 heats the second bypass line L422.

In the temperature adjusting device 422, the fluid is supplied into the processing container 411 through the third branch line L421 by closing the opening/closing valve V50 and opening the opening/closing valve V421. In this case, the fluid of which the flow velocity has been reduced by the orifice OR422 is introduced to the first branch line L44 from the third branch line L421 through the second bypass line L422. Thus, it is possible to suppress the backflow of the fluid from the processing container 411 toward the upstream side of the first branch line L44. Therefore, it is possible to suppress the contamination caused by the residues of IPA in the first branch line L44.

Further, the fluid is supplied into the processing container 411 through the first branch line L44 by closing the opening/closing valve V421 and opening the opening/closing valve V50. In this case, the fluid of which the flow velocity has been reduced by the orifice OR422 is introduced to the third branch line L421 from the first branch line L44 through the second bypass line L422. Thus, it is possible to suppress the backflow of the fluid from the processing container 411 toward the upstream side of the third branch line L421. Therefore, it is possible to suppress the contamination caused by the residues of IPA in the third branch line L421.

The discharge device 43 is equipped with a discharge line L49. The discharge line L49 is connected to the processing container 411. A back pressure valve BV41 and an opening/closing valve V49 are provided in sequence from an upstream side of the discharge line L49. A line heater LH46 is provided in the discharge line L49. Sensors, such as a temperature sensor and a pressure sensor, may be provided at various positions in the discharge line L49.

The back pressure valve BV41, the opening/closing valve V49, and the line heater LH46 may be the same as the back pressure valve BV11, the opening/closing valve V17, and the line heater LH15, respectively.

Like the controller 14, the controller 44 receives measurement signals from various sensors and transmits control signals to various functional elements. The controller 44 is, for example, a computer, and includes an operator 441 and a storage 442. The operator 441 and the storage 442 may be the same as the operator 141 and the storage 142, respectively.

### Fifth Exemplary Embodiment

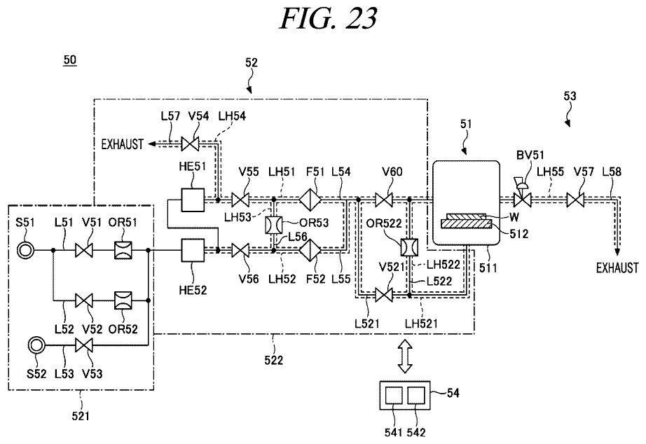

A substrate processing apparatus 50 according to a fifth exemplary embodiment will be described with reference to FIG. 23. FIG. 23 is a view illustrating the substrate processing apparatus 50 according to the fifth exemplary embodiment.

The substrate processing apparatus 50 is equipped with a processing device 51, a fluid supply system 52, a discharge device 53, and a controller 54.

The processing device 51 may be the same as the processing device 11. The processing device 51 is equipped with a processing container 511 and a holding plate 512.

The fluid supply system 52 is equipped with a processing fluid supply 521 and a temperature adjusting device 522.

The processing fluid supply 521 may be the same as the processing fluid supply 121. The processing fluid supply 521 is equipped with a processing fluid source S51, a first supply line L51, an opening/closing valve V51, an orifice OR51, a second supply line L52, an opening/closing valve V52, an orifice OR52, an inert gas source S52, a third supply line L53, and an opening/closing valve V53.

The temperature adjusting device 522 is connected to the processing fluid supply 521 and the processing container 511. The temperature adjusting device 522 allows a temperature-adjusted fluid to flow inside the processing container 511. The fluid includes a processing fluid and an inert gas. The temperature adjusting device 522 is equipped with a first branch line L54, a second branch line L55, a first bypass line L56, a first discharge line L57, a third branch line L521, and a second bypass line L522.

The first branch line L54 is connected to a side of the processing container 511. The first branch line L54 supplies the fluid from the side of the processing container 511 toward the substrate W. A heating mechanism HE51, an opening/closing valve V55, a filter F51, and an opening/closing valve V60 are provided in sequence from an upstream side of the first branch line L54. A line heater LH51 is provided on a downstream side of the heating mechanism HE51 in the first branch line L54. Sensors, such as a temperature sensor and a pressure sensor, may be provided at various positions in the first branch line L54.

A heating mechanism HE52, an opening/closing valve V56, and a filter F52 are provided in sequence from an upstream side of the second branch line L55. A line heater LH52 is provided on a downstream side of the heating mechanism HE52 in the second branch line L55. Sensors, such as a temperature sensor and a pressure sensor, may be provided at various positions in the second branch line L55.

The first branch line L54 is branched off from the second branch line L55 between the heating mechanism HE52 and the opening/closing valve V56. The second branch line L55 joins with the first branch line L54 between the filter F51 and the opening/closing valve V60.

The heating mechanism HE51 and the heating mechanism HE52 are provided in series. The heating mechanism HE51 heats the fluid supplied from the processing fluid supply 521 to a first temperature, and supplies the fluid of the first temperature to the downstream side. The first temperature may be, for example, from 100 °C to 120 °C.

The opening/closing valve V55 is configured to switch ON and OFF of a flow of the fluid. In the open state, the opening/closing valve V55 allows the fluid to flow to the filter F51 on a downstream side. Also, in the closed state, the opening/closing valve V55 does not allow the fluid to flow to the filter F51 on the downstream side.

The filter F51 filters the fluid flowing inside the first branch line L54 to remove foreign matters contained in the fluid. Thus, it is possible to suppress the occurrence of particles on the surface of the substrate W during a processing of the substrate W using the fluid.

The opening/closing valve V60 is configured to switch ON and OFF of a flow of the fluid. In the open state, the opening/closing valve V60 allows the fluid to flow to the processing container 511 on a downstream side. Also, in the closed state, the opening/closing valve V60 does not allow the fluid to flow to the processing container 511 on the downstream side.

The line heater LH51 heats the first branch line L54 on the downstream side of the heating mechanism HE51. The line heater LH51 suppresses a decrease in temperature of the fluid, which has been heated to the first temperature by the heating mechanism HE51, when the fluid flows inside the first branch line L54.

The heating mechanism HE52 heats the fluid supplied from the processing fluid supply 521 to a second temperature, and supplies the fluid of the second temperature to the downstream side. The second temperature is lower than the first temperature. The second temperature may be, for example, from 80 °C to 90 °C.

The opening/closing valve V56 is configured to switch ON and OFF of a flow of the fluid. In the open state, the opening/closing valve V56 allows the fluid to flow to the filter F52 on a downstream side. Also, in the closed state, the opening/closing valve V56 does not allow the fluid to flow to the filter F52 on the downstream side.

The filter F52 filters the fluid flowing inside the second branch line L55 to remove foreign matters contained in the fluid. Thus, it is possible to suppress the occurrence of particles on the surface of the substrate W during the processing of the substrate W using the fluid.

The line heater LH52 heats the second branch line L55 on the downstream side of the heating mechanism HE52. The line heater LH52 suppresses a decrease in temperature of the fluid, which has been heated to the second temperature by the heating mechanism HE52, when the fluid flows inside the second branch line L55.

The first bypass line L56 communicates with a position between the opening/closing valve V55 and the filter F51 in the first branch line L54 and a position between the opening/closing valve V56 and the filter F52 in the second branch line L55. An orifice OR53 is provided in the first bypass line L56. A line heater LH53 is provided in the first bypass line L56.

The orifice OR53 serves to adjust a pressure by reducing a flow velocity of the fluid flowing inside the first bypass line L56.

The line heater LH53 heats the first bypass line L56.

In the temperature adjusting device 522, the fluid, which has been heated to the second temperature by the heating mechanism HE52, is supplied into the processing container 511 through the second branch line L55 by closing the opening/closing valve V55 and opening the opening/closing valve V56. In this case, the fluid of which the flow velocity has been reduced by the orifice OR53 is introduced to the first branch line L54 from the second branch line L55 through the first bypass line L56. Thus, it is possible to suppress backflow of the fluid from a junction between the first branch line L54 and the second branch line L55 toward the upstream side of the first branch line L54. Therefore, it is possible to suppress contamination in the first branch line L54, the filter F51, and the like.

Further, the fluid, which has been heated to the first temperature by the heating mechanism HE51, is supplied into the processing container 511 through the first branch line L54 by closing the opening/closing valve V56 and opening the opening/closing valve V55. In this case, the fluid of which the flow velocity has been reduced by the orifice OR53 is introduced to the second branch line L55 from the first branch line L54 through the first bypass line L56. Thus, it is possible to suppress the backflow of the fluid from the junction between the first branch line L54 and the second branch line L55 toward the upstream side of the second branch line L55. Therefore, it is possible to suppress the contamination in the second branch line L55, the filter F52, and the like.

Since the opening/closing valve V55 and the opening/closing valve V56 are exclusively opened or closed, the temperature of the fluid flowing inside the processing container 511 can be changed. Further, when both the opening/closing valve V55 and the opening/closing valve V56 are opened, the fluid, which has been heated to the first temperature by the heating mechanism HE51, is mixed with the fluid, which has been heated to the second temperature by the heating mechanism HE52 and then supplied into the processing container 511. In this case, the fluid of an intermediate temperature between the first temperature and the second temperature can be supplied into the processing container 511. Thus, by controlling the opening and closing of the opening/closing valve V55 and the opening/closing valve V56, the temperature of the fluid flowing inside the processing container 511 can be changed in three stages.

The first discharge line L57 discharges the fluid in the first branch line L54. The first discharge line L57 is branched off from the first branch line L54 between the heating mechanism HE51 and the opening/closing valve V55. An opening/closing valve V54 is provided in the first discharge line L57. A line heater LH54 is provided in the first discharge line L57. An orifice may be provided in the first discharge line L57.

The opening/closing valve V54 is configured to switch ON and OFF of a flow of the fluid. In the open state, the opening/closing valve V54 allows the fluid to flow to the first discharge line L57 on a downstream side. Also, in the closed state, the opening/closing valve V54 does not allow the fluid to flow to the first discharge line L57 on the downstream side.

The line heater LH54 heats the first discharge line L57.

The third branch line L521 is branched off from the first branch line L54 between the filter F51 and the opening/closing valve V60. The third branch line L521 is connected to a bottom of the processing container 511. The third branch line L521 supplies the fluid from the bottom of the processing container 511 toward the substrate W.

An opening/closing valve V521 is provided in the third branch line L521. A line heater LH521 is provided in the third branch line L521. Sensors, such as a temperature sensor and a pressure sensor, may be provided at various positions in the third branch line L521.

The opening/closing valve V521 is configured to switch ON and OFF of a flow of the fluid. In the open state, the opening/closing valve V521 allows the fluid to flow to the processing container 511 on a downstream side. Also, in the closed state, the opening/closing valve V521 does not allow the fluid to flow to the processing container 511 on the downstream side.

The line heater LH521 heats the third branch line L521. The line heater LH521 suppresses a decrease in temperature of the fluid, which has been heated to the first temperature by the heating mechanism HE51, and the fluid, which has been heated to the second temperature by the heating mechanism HE52, when the fluid flows inside the third branch line L521.

The second bypass line L522 communicates with a position on a downstream side of the opening/closing valve V60 in the first branch line L54 and a position on a downstream side of the opening/closing valve V521 in the third branch line L521. An orifice OR522 is provided in the second bypass line L522. A line heater LH522 is provided in the second bypass line L522.

The orifice OR522 serves to adjust a pressure by reducing a flow velocity of the fluid flowing inside the second bypass line L522.

The line heater LH522 heats the second bypass line L522.

In the temperature adjusting device 522, the fluid is supplied into the processing container 511 through the third branch line L521 by closing the opening/closing valve V60 and opening the opening/closing valve V521. In this case, the fluid of which the flow velocity has been reduced by the orifice OR522 is introduced to the first branch line L54 from the third branch line L521 through the second bypass line L522. Thus, it is possible to suppress the backflow of the fluid from the processing container 511 toward the upstream side of the first branch line L54. Therefore, it is possible to suppress the contamination caused by the residues of IPA in the first branch line L54.

Further, the fluid is supplied into the processing container 511 through the first branch line L54 by closing the opening/closing valve V521 and opening the opening/closing valve V60. In this case, the fluid of which the flow velocity has been reduced by the orifice OR522 is introduced to the third branch line L521 from the first branch line L54 through the second bypass line L522. Thus, it is possible to suppress the backflow of the fluid from the processing container 511 toward an upstream side of the third branch line L521. Therefore, it is possible to suppress the contamination caused by the residues of IPA in the third branch line L521.

The discharge device 53 is equipped with a discharge line L58. The discharge line L58 is connected to the processing container 511. A back pressure valve BV51 and an opening/closing valve V57 are provided in sequence from an upstream side of the discharge line L58. A line heater LH55 is provided in the discharge line L58. Sensors, such as a temperature sensor and a pressure sensor, may be provided at various positions in the discharge line L58.

The back pressure valve BV51, the opening/closing valve V57, and the line heater LH55 may be the same as the back pressure valve BV11, the opening/closing valve V17, and the line heater LH15, respectively.

Like the controller 14, the controller 54 receives measurement signals from various sensors and transmits control signals to various functional elements. The controller 54 is, for example, a computer, and includes an operator 541 and a storage 542. The operator 541 and the storage 542 may be the same as the operator 141 and the storage 142, respectively.

### Sixth Exemplary Embodiment

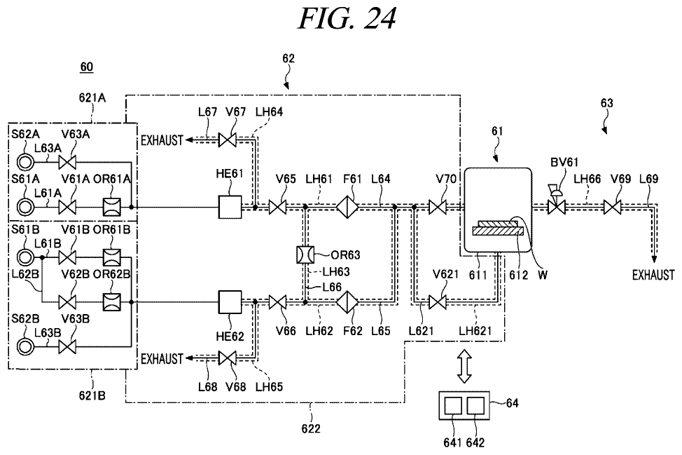

A substrate processing apparatus 60 according to a sixth exemplary embodiment will be described with reference to FIG. 24. FIG. 24 is a view illustrating the substrate processing apparatus 60 according to the sixth exemplary embodiment.

The substrate processing apparatus 60 is equipped with a processing device 61, a fluid supply system 62, a discharge device 63, and a controller 64.

The processing device 61 may be the same as the processing device 11. The processing device 61 is equipped with a processing container 611 and a holding plate 612.

The fluid supply system 62 is equipped with a processing fluid supply 621A, a processing fluid supply 621B, and a temperature adjusting device 622.

The processing fluid supply 621A and the processing fluid supply 621B may be the same as the processing fluid supply 221A and the processing fluid supply 221B, respectively. The processing fluid supply 621A is equipped with a processing fluid source S61A, a first supply line L61A, an opening/closing valve V61A, an orifice OR61A, an inert gas source S62A, a third supply line L63A, and an opening/closing valve V63A. The processing fluid supply 621B is equipped with a processing fluid source S61B, a first supply line L61B, an opening/closing valve V61B, an orifice OR61B, a second supply line L62B, an opening/closing valve V62B, an orifice OR62B, an inert gas source S62B, a third supply line L63B, and an opening/closing valve V63B.

The temperature adjusting device 622 is connected to the processing fluid supply 621A, the processing fluid supply 621B, and the processing container 611. The temperature adjusting device 622 allows a temperature-adjusted fluid to flow inside the processing container 611. The fluid includes a processing fluid and an inert gas. The temperature adjusting device 622 is equipped with a first branch line L64, a second branch line L65, a bypass line L66, a first discharge line L67, a second discharge line L68, and a third branch line L621.

The first branch line L64 is connected to the processing fluid supply 621A. The fluid is supplied from the processing fluid supply 621A to the first branch line L64. The first branch line L64 is connected to a side of the processing container 611. The first branch line L64 supplies the fluid from the side of the processing container 611 toward the substrate W. A heating mechanism HE61, an opening/closing valve V65, a filter F61, and an opening/closing valve V70 are provided in sequence from an upstream side of the first branch line L64. A line heater LH61 is provided on a downstream side of the heating mechanism HE61 in the first branch line L64. Sensors, such as a temperature sensor and a pressure sensor, may be provided at various positions in the first branch line L64.

The heating mechanism HE61 is provided in parallel with the heating mechanism HE62. The heating mechanism HE61 heats the fluid supplied from the processing fluid supply 621A to a first temperature, and supplies the fluid of the first temperature to the downstream side. The first temperature may be, for example, from 100 °C to 120 °C.

The opening/closing valve V65 is configured to switch ON and OFF of a flow of the fluid. In the open state, the opening/closing valve V65 allows the fluid to flow to the filter F61 on a downstream side. Also, in the closed state, the opening/closing valve V65 does not allow the fluid to flow to the filter F61 on the downstream side.

The filter F61 filters the fluid flowing inside the first branch line L64 to remove foreign matters contained in the fluid. Thus, it is possible to suppress the occurrence of particles on the surface of the substrate W during a drying processing of the substrate W using the fluid.

The opening/closing valve V70 is configured to switch ON and OFF of a flow of the fluid. In the open state, the opening/closing valve V70 allows the fluid to flow to the processing container 611 on a downstream side. Also, in the closed state, the opening/closing valve V70 does not allow the fluid to flow to the processing container 611 on the downstream side.

The line heater LH61 heats the first branch line L64 on the downstream side of the heating mechanism HE61. The line heater LH61 suppresses a decrease in temperature of the fluid, which has been heated to the first temperature by the heating mechanism HE61, when the fluid flows inside the first branch line L64.

The second branch line L65 is connected to the processing fluid supply 621B. The fluid is supplied from the processing fluid supply 621B to the second branch line L65. The second branch line L65 joins with the first branch line L64 between the filter F61 and the opening/closing valve V70. A heating mechanism HE62, an opening/closing valve V66, and a filter F62 are provided in sequence from an upstream side of the second branch line L65. A line heater LH62 is provided on a downstream side of the heating mechanism HE62 in the second branch line L65. Sensors, such as a temperature sensor and a pressure sensor, may be provided at various positions in the second branch line L65.

The heating mechanism HE62 heats the fluid supplied from the processing fluid supply 621B to a second temperature, and supplies the fluid of the second temperature to the downstream side. The second temperature is lower than the first temperature. The second temperature may be, for example, from 80 °C to 90 °C.

The opening/closing valve V66 is configured to switch ON and OFF of a flow of the fluid. In the open state, the opening/closing valve V66 allows the fluid to flow to the filter F62 on a downstream side. Also, in the closed state, the opening/closing valve V66 does not allow the fluid to flow to the filter F62 on the downstream side.

The filter F62 filters the fluid flowing inside the second branch line L65 to remove foreign matters contained in the fluid. Thus, it is possible to suppress the occurrence of particles on the surface of the substrate W during the drying processing of the substrate W using the fluid.

The line heater LH62 heats the second branch line L65 on the downstream side of the heating mechanism HE62. The line heater LH62 suppresses a decrease in temperature of the fluid, which has been heated to the second temperature by the heating mechanism HE62, when the fluid flows inside the second branch line L65.

The bypass line L66 communicates with a position between the opening/closing valve V65 and the filter F61 in the first branch line L64 and a position between the opening/closing valve V66 and the filter F62 in the second branch line L65. An orifice OR63 is provided in the bypass line L66. A line heater LH63 is provided in the bypass line L66.

The orifice OR63 serves to adjust a pressure by reducing a flow velocity of the fluid flowing inside the bypass line L66.

The line heater LH63 heats the bypass line L66.

In the temperature adjusting device 622, the fluid, which has been heated to the second temperature by the heating mechanism HE62, is supplied into the processing container 611 through the second branch line L65 by closing the opening/closing valve V65 and opening the opening/closing valve V66. In this case, the fluid of which the flow velocity has been reduced by the orifice OR63 is introduced to the first branch line L64 from the second branch line L65 through the bypass line L66. Thus, it is possible to suppress backflow of the fluid from the junction between the first branch line L64 and the second branch line L65 toward the upstream side of the first branch line L64. Therefore, it is possible to suppress contamination caused in the first branch line L64, the filter F61, and the like.

Further, the fluid, which has been heated to the first temperature by the heating mechanism HE61, is supplied into the processing container 611 through the first branch line L64 by closing the opening/closing valve V66 and opening the opening/closing valve V65. In this case, the fluid of which the flow velocity has been reduced by the orifice OR63 is introduced to the second branch line L65 from the first branch line L64 through the bypass line L66. Thus, it is possible to suppress the backflow of the fluid from the junction between the first branch line L64 and the second branch line L65 toward the upstream side of the second branch line L65. Therefore, it is possible to suppress the contamination caused in the second branch line L65, the filter F62, and the like.

Since the opening/closing valve V65 and the opening/closing valve V66 are exclusively opened or closed, the temperature of the fluid flowing inside the processing container 611 can be changed. Further, when both the opening/closing valve V65 and the opening/closing valve V66 are opened, the fluid, which has been heated to the first temperature by the heating mechanism HE61, is mixed with the fluid, which has been heated to the second temperature by the heating mechanism HE62 and then supplied into the processing container 611. In this case, the fluid of an intermediate temperature between the first temperature and the second temperature can be supplied into the processing container 611. Thus, by controlling the opening and closing of the opening/closing valve V65 and the opening/closing valve V66, the temperature of the fluid flowing inside the processing container 611 can be changed in three stages.

The first discharge line L67 discharges the fluid in the first branch line L64. The first discharge line L67 is branched off from the first branch line L64 between the heating mechanism HE61 and the opening/closing valve V65. An opening/closing valve V67 is provided in the first discharge line L67. A line heater LH64 is provided in the first discharge line L67. An orifice may be provided in the first discharge line L67.

The opening/closing valve V67 is configured to switch ON and OFF of a flow of the fluid. In the open state, the opening/closing valve V67 allows the fluid to flow to the first discharge line L67 on a downstream side. Also, in the closed state, the opening/closing valve V67 does not allow the fluid to flow to the first discharge line L67 on the downstream side.

The line heater LH64 heats the first discharge line L67.

The second discharge line L68 discharges the fluid in the second branch line L65. The second discharge line L68 is branched off from the second branch line L65 between the heating mechanism HE62 and the opening/closing valve V66. An opening/closing valve V68 is provided in the second discharge line L68. A line heater LH65 is provided in the second discharge line L68. An orifice may be provided in the second discharge line L68.

The opening/closing valve V68 is configured to switch ON and OFF of a flow of the fluid. In the open state, the opening/closing valve V68 allows the fluid to flow to the second discharge line L68 on a downstream side. Also, in the closed state, the opening/closing valve V68 does not allow the fluid to flow to the second discharge line L68 on the downstream side.

The line heater LH65 heats the second discharge line L68.

The third branch line L621 is branched off from the first branch line L64 between the filter F61 and the opening/closing valve V70. The third branch line L621 is connected to a bottom of the processing container 611. The third branch line L621 supplies the fluid from the bottom of the processing container 611 toward the substrate W.

An opening/closing valve V621 is provided in the third branch line L621. A line heater LH621 is provided in the third branch line L621. Sensors, such as a temperature sensor and a pressure sensor, may be provided at various positions in the third branch line L621.

The opening/closing valve V621 is configured to switch ON and OFF of a flow of the fluid. In the open state, the opening/closing valve V621 allows the fluid to flow to the processing container 611 on a downstream side. Also, in the closed state, the opening/closing valve V621 does not allow the fluid to flow to the processing container 611 on the downstream side.

The line heater LH621 heats the third branch line L621. The line heater LH621 suppresses the decrease in temperature of the fluid, which has been heated to the first temperature by the heating mechanism HE61, and the fluid, which has been heated to the second temperature by the heating mechanism HE62, when the fluid flows inside the third branch line L621.

In the temperature adjusting device 622, the fluid is supplied into the processing container 611 through the third branch line L621 by closing the opening/closing valve V70 and opening the opening/closing valve V621. Further, the fluid is supplied into the processing container 611 through the first branch line L64 by closing the opening/closing valve V621 and opening the opening/closing valve V70.

The discharge device 63 is equipped with a discharge line L69. The discharge line L69 is connected to the processing container 611. A back pressure valve BV61 and an opening/closing valve V69 are provided in sequence from an upstream side of the discharge line L69. A line heater LH66 is provided in the discharge line L69. Sensors, such as a temperature sensor and a pressure sensor, may be provided at various positions in the discharge line L69.

The back pressure valve BV61, the opening/closing valve V69, and the line heater LH66 may be the same as the back pressure valve BV11, the opening/closing valve V17, and the line heater LH15, respectively.

Like the controller 14, the controller 64 receives measurement signals from various sensors and transmits control signals to various functional elements. The controller 64 is, for example, a computer, and includes an operator 641 and a storage 642. The operator 641 and the storage 642 may be the same as the operator 141 and the storage 142, respectively.

In the above-described exemplary embodiments, the opening/closing valves V11 and V21 are examples of a first supply valve, and the opening/closing valves V12 and V22 are examples of a second supply valve. The opening/closing valves V15 and V25 are examples of a first opening/closing valve, the opening/closing valves V16 and V26 are examples of a second opening/closing valve, and the opening/closing valve V24 is an example of a third opening/closing valve. The opening/closing valve V27 is an example of a first discharge valve, the opening/closing valve V28 is an example of a second discharge valve, and the opening/closing valve V29 is an example of a third discharge valve. The heating mechanisms HE11 and HE21 are examples of a first heating mechanism, and the heating mechanisms HE12 and HE22 are examples of a second heating mechanism. The orifices OR13 and OR23 are examples of a first diaphragm. The first branch lines L14 and L24 and the second branch lines L15 and L25 are examples of a fluid supply line.

The exemplary embodiments disclosed herein are illustrative in all aspects and do not limit the present disclosure. The above-described exemplary embodiments may be omitted, substituted, or changed in various forms without departing from the scope and spirit of the appended claims.

This PCT application claims the benefit of priority to Japanese Patent Application No. 2022-168324 filed on Oct. 20, 2022 and incorporated herein by reference in its entirety.

### EXPLANATION OF CODES

10, 20: Substrate processing apparatus
11, 21: Processor
111, 211: Processing container
12, 22: Fluid supply system
121, 221: Processing fluid supply
122, 222: Temperature adjuster
HE11, HE21: Heating mechanism
HE12, HE22: Heating mechanism
L14, L24: First branch line
L15, L25: Second branch line
V11, V21: Opening/closing valve
V12, V22: Opening/closing valve

1. A fluid supply system configured to supply a fluid into a processing container in which a substrate is processed, comprising:
a processing fluid supply configured to supply a processing fluid;
a fluid supply line connected to the processing fluid supply and the processing container, the fluid supply line configured to allow a temperature-adjusted processing fluid to flow inside the processing container;
a first heating mechanism provided in the fluid supply line and configured to heat the processing fluid to a first temperature; and
a second heating mechanism provided in the fluid supply line and configured to heat the processing fluid to a second temperature lower than the first temperature, wherein
the processing fluid supply is equipped with a flow rate adjustment mechanism configured to adjust a flow rate of the processing fluid, and
the fluid supply line is equipped with:
a first branch line configured to allow the processing fluid to pass through the first heating mechanism and then flow inside the processing container; and
a second branch line configured to allow the processing fluid to pass through the second heating mechanism and then flow inside the processing container.

2. The fluid supply system of claim 1, wherein
the first branch line is equipped with a first opening/closing valve on a downstream side of the first heating mechanism,
the second branch line is equipped with a second opening/closing valve on a downstream side of the second heating mechanism,
the fluid supply line is equipped with a bypass line, which communicates the first branch line with the second branch line, on a downstream side of the first opening/closing valve and a downstream side of the second opening/closing valve, and
a first diaphragm is provided in the bypass line.

3. The fluid supply system of claim 1, further comprising:
circuitry configured to control components of the fluid supply system, wherein
the first branch line is equipped with a first opening/closing valve on a downstream side of the first heating mechanism,
the second branch line is equipped with a second opening/closing valve on a downstream side of the second heating mechanism, and
the circuitry is configured to change a temperature of the processing fluid, which is allowed to flow inside the processing container, by controlling opening and closing of the first opening/closing valve and the second opening/closing valve.

4. The fluid supply system of claim 1, wherein
the first heating mechanism and the second heating mechanism are provided in series, and
the first branch line is connected to a first discharge line configured to discharge the processing fluid in the first branch line.

5. The fluid supply system of claim 2, wherein
the first heating mechanism is provided in parallel with the second heating mechanism,
the first branch line is equipped with a first discharge valve and connected to a first discharge line configured to discharge the processing fluid in the first branch line,
the second branch line is equipped with a second discharge valve and connected to a second discharge line configured to discharge the processing fluid in the second branch line, and
the second branch line is equipped with a third opening/closing valve on an upstream side of the second heating mechanism.

6. The fluid supply system of claim 5, further comprising:
circuitry configured to control components of the fluid supply system, wherein
the controller is configured to:
cause the substrate to be carried into the processing container;
supply the processing fluid of the second temperature into the processing container by controlling the second opening/closing valve and the third opening/closing valve to open after the substrate is carried into the processing container;
supply the processing fluid of the first temperature into the processing container by controlling the second opening/closing valve and the third opening/closing valve to close and the first opening/closing valve to open after the supplying of the processing fluid of the second temperature; and
decompress the second branch line by controlling the second discharge valve to open, and
the decompressing of the second branch line is performed in parallel with the supplying of the processing fluid of the first temperature into the processing container.

7. The fluid supply system of claim 2, further comprising:
circuitry configured to control components of the fluid supply system,
wherein the circuitry is configured to change a temperature of the processing fluid, which is allowed to flow inside the processing container, by controlling opening and closing of the first opening/closing valve and the second opening/closing valve depending on a processing state of the substrate in the processing container.

8. The fluid supply system of claim 1, further comprising:
circuitry configured to control components of the fluid supply system, wherein
the processing fluid supply is equipped with a first supply line and a second supply line which are provided in parallel with each other,
the flow rate adjustment mechanism is equipped with a first supply valve provided in the first supply line and a second supply valve provided in the second supply line, and
the circuitry is configured to change the flow rate of the processing fluid, which is allowed to flow inside the processing container, by controlling opening and closing of the first supply valve and the second supply valve depending on a processing state of the substrate in the processing container.

9. The fluid supply system of claim 2, further comprising:
circuitry configured to control components of the fluid supply system,
wherein the circuitry is configured to:
cause the substrate to be carried into the processing container;
supply the processing fluid to the fluid supply line at a first flow rate by controlling the flow rate adjustment mechanism and supply the processing fluid into the processing container at the first flow rate and the second temperature by controlling opening-the second opening/closing valve to open; and
supply the processing fluid to the fluid supply line at a second flow rate by controlling the flow rate adjustment mechanism and supply the processing fluid into the processing container at the second flow rate and the first temperature by controlling the first opening/closing valve to open after the supplying of the processing fluid into the processing container at the first flow rate and the second temperature.

10. A substrate processing apparatus, comprising:
the fluid supply system claimed in claim 7; and
a discharge device equipped with a third discharge valve and configured to discharge the processing fluid in the processing container,
wherein the circuitry is configured to:
cause the substrate to be carried into the processing container;
increase a pressure inside the processing container by supplying the processing fluid to the fluid supply line at a first flow rate by controlling the flow rate adjustment mechanism and by supplying the processing fluid into the processing container at the first flow rate and the second temperature by controlling the second opening/closing valve to open and controlling the third discharge valve to open; and
increasing, after the increasing of the pressure inside the processing container by supplying the processing fluid to the fluid supply line at the first flow rate, the pressure inside the processing container by supplying the processing fluid to the fluid supply line at a second flow rate by controlling the flow rate adjustment mechanism and by supplying the processing fluid into the processing container at the second flow rate and the first temperature by closing-causing the second opening/closing valve to close and causing the first opening/closing valve to open.

11. A substrate processing method performed in a fluid supply system configured to supply a fluid into a processing container in which a substrate is processed, the method comprising:
supplying a processing fluid via a processing fluid supply;
allowing a temperature-adjusted processing fluid to flow inside the processing container via a fluid supply line connected to the processing fluid supply and the processing container;
heating the processing fluid to a first temperature via a first heating mechanism provided in the fluid supply line first; and
heating the processing fluid to a second temperature lower than the first temperature via a second heating mechanism provided in the fluid supply line, wherein
supplying the processing fluid includes adjusting a flow rate of the processing fluid via a flow rate adjustment mechanism,
allowing the temperature-adjusted processing fluid to flow inside the processing container includes:
allowing the processing fluid to pass through the first heating mechanism and then flow inside the processing container via a first branch line; and
allowing the processing fluid to pass through the second heating mechanism and then flow inside the processing container via a second branch line, and
the substrate is processed in the processing container by supplying the fluid into the processing container.

12. The substrate processing method of claim 11, wherein
the first branch line is equipped with a first opening/closing valve on a downstream side of the first heating mechanism,
the second branch line is equipped with a second opening/closing valve on a downstream side of the second heating mechanism,
the fluid supply line is equipped with a bypass line, which communicates the first branch line with the second branch line, on a downstream side of the first opening/closing valve and a downstream side of the second opening/closing valve, and
a first diaphragm is provided in the bypass line.

13. The substrate processing method of claim 11, wherein
the first branch line is equipped with a first opening/closing valve on a downstream side of the first heating mechanism,
the second branch line is equipped with a second opening/closing valve on a downstream side of the second heating mechanism, and
the method includes changing a temperature of the processing fluid, which is allowed to flow inside the processing container, by opening and closing the first opening/closing valve and the second opening/closing valve.

14. The substrate processing method of claim 11, wherein
the first heating mechanism and the second heating mechanism are provided in series, and
the first branch line is connected to a first discharge line configured to discharge the processing fluid in the first branch line.

15. The substrate processing method of claim 12, wherein
the first heating mechanism is provided in parallel with the second heating mechanism,
the first branch line is equipped with a first discharge valve and connected to a first discharge line configured to discharge the processing fluid in the first branch line,
the second branch line is equipped with a second discharge valve and connected to a second discharge line configured to discharge the processing fluid in the second branch line, and
the second branch line is equipped with a third opening/closing valve on an upstream side of the second heating mechanism.

16. The substrate processing method of claim 15, further comprising:
carrying the substrate into the processing container;
supplying the processing fluid of the second temperature into the processing container by opening the second opening/closing valve and the third opening/closing valve after the carrying of the substrate in the processing container;
supplying the processing fluid of the first temperature into the processing container by closing the second opening/closing valve and the third opening/closing valve and opening the first opening/closing valve after the supplying of the processing fluid of the second temperature; and
decompressing the second branch line by opening the second discharge valve,
wherein the decompressing the second branch line is performed in parallel with the supplying of the processing fluid of the first temperature into the processing container.

17. The substrate processing method of claim 12, further comprising:
changing a temperature of the processing fluid, which is allowed to flow inside the processing container, by controlling opening and closing of the first opening/closing valve and the second opening/closing valve depending on a processing state of the substrate in the processing container.

18. The substrate processing method of claim 11, wherein
the processing fluid supply is equipped with a first supply line and a second supply line which are provided in parallel with each other,
the flow rate adjustment mechanism is equipped with a first supply valve provided in the first supply line and a second supply valve provided in the second supply line, and
the method includes changing the flow rate of the processing fluid, which is allowed to flow inside the processing container, by controlling opening and closing of the first supply valve and the second supply valve depending on a processing state of the substrate in the processing container.

19. The substrate processing method of claim 12, further comprising:
carrying the substrate into the processing container;
supplying the processing fluid to the fluid supply line at a first flow rate by controlling the flow rate adjustment mechanism and supplying the processing fluid into the processing container at the first flow rate and the second temperature by opening the second opening/closing valve; and
supplying the processing fluid to the fluid supply line at a second flow rate by controlling the flow rate adjustment mechanism and supplying the processing fluid into the processing container at the second flow rate and the first temperature by opening the first opening/closing valve after the supplying of the processing fluid into the processing container at the first flow rate and the second temperature.

20. The substrate processing method of claim 17, wherein
a discharge device is equipped with a third discharge valve and configured to discharge the processing fluid in the processing container, and
the method includes:
carrying the substrate into the processing container;
increasing a pressure inside the processing container by supplying the processing fluid to the fluid supply line at a first flow rate by controlling the flow rate adjustment mechanism and by supplying the processing fluid into the processing container at the first flow rate and the second temperature by opening the second opening/closing valve and closing the third discharge valve; and
increasing, after the increasing of the pressure inside the processing container by supplying the processing fluid to the fluid supply line at the first flow rate, the pressure inside the processing container by supplying the processing fluid to the fluid supply line at a second flow rate by controlling the flow rate adjustment mechanism and by supplying the processing fluid into the processing container at the second flow rate and the first temperature by closing the second opening/closing valve and opening the first opening/closing valve.
